(19) United States
(12) Patent Application Publication
(10) Pub. No.: US 2022/0026264 A1
(43) Pub. Date: Jan. 27, 2022

(54) Machine Condition Monitoring Using Phase Adjusted Frequency Referenced Vector Averaging

(71) Applicant: NATIONAL INSTRUMENTS CORPORATION, Austin, TX (US)

(72) Inventors: Douglas S. Bendele, Austin, TX (US); James C. Nagle, Austin, TX (US); Alan D. Armstead, Ozawkie, KS (US); Preston T. Johnson, Austin, TX (US)

(21) Appl. No.: 17/496,283

(22) Filed: Oct. 7, 2021

Related U.S. Application Data
(63) Continuation of application No. 14/940,942, filed on Nov. 13, 2015.
(60) Provisional application No. 62/135,599, filed on Mar. 19, 2015.

(51) Int. Cl. G01H 1/00

(52) U.S. Cl. CPC G01H 1/003; H04W 16/14

(57) ABSTRACT

System and method for machine condition monitoring using phase adjusted vector averaging. An analog signal from a sensor measuring a machine parameter may be acquired, thereby generating a first digital signal that includes multiple analysis blocks of data. For each analysis block, a complex valued frequency spectrum (CVFS) may be computed via a Discrete Fourier transform (DFT), at least one reference frequency may be specified, and a complex valued phase compensation vector that preserves magnitude while adjusting phase constructed to achieve coherence between reference frequency components (RFCs) and the selected analysis block. The CVFS may be phase compensated by multiplying the complex valued phase compensation vector with the complex-valued frequency spectrum. The complex valued frequency spectra of the analysis blocks may be vector averaged, thereby improving signal to noise ratio at specified frequencies. RFCs in the averaged spectrum may be identified, thereby generating average RFCs analyzable to determine machine condition.

### PRIORITY DATA

This application is a continuation of U.S. application Ser. No. 14/940,942, titled “Machine Condition Monitoring Using Phase Adjusted Frequency Referenced Vector Averaging”, filed Nov. 13, 2015, which claims benefit of priority to U.S. Provisional Application No. 62/135,599, titled “Machine Condition Monitoring Using Phase Adjusted Frequency Referenced Vector Averaging”, filed Mar. 19, 2015, whose inventors were Douglas S. Bendele, James C. Nagle, Alan D. Armstead, and Preston T. Johnson, which are hereby incorporated by reference in their entirety as though fully and completely set forth herein.

The claims in the instant application are different than those of the parent application or other related applications. The Applicant rescinds any disclaimer of claim scope made in the parent application or any predecessor application in relation to the instant application. Therefore, any such previous disclaimer and the cited references that it was made to avoid, may need to be revisited. Further, any disclaimer made in the instant application should not be read into or against the parent application or other related applications.

### FIELD OF THE INVENTION

The present invention relates to the field of machine condition monitoring, and more particularly to systems and methods for machine condition monitoring using phase adjusted frequency referenced vector averaging of machine condition signals, e.g., of rotational machinery.

### DESCRIPTION OF THE RELATED ART

Machine conditioning monitoring is important in many fields, such as industrial manufacturing, heavy equipment, transportation, oil and gas acquisition and processing, and power generation and distribution, among others, where one or more parameters indicative of the condition of a machine or system are monitored in order to detect or identify substantial changes in the value of the parameter(s) indicative of a developing fault, e.g., due to wear or disruptive events.

Vibration levels are indicators of machine health, and so monitoring of (e.g., rotational) machinery condition generally involves vibration analysis, which may include analysis of harmonic content in a monitored signal, referred to as order analysis. For example, order components of the signal are the components at constant multiples of the fundamental frequency f₀ of the signal, e.g., n*f₀, where n is any positive number. Although broadband vibration energy contributes to the overall vibration level of a machine, this same broadband energy masks order and frequency components and makes early detection of specific machine faults more difficult.

Time-synchronous averaging is one technique that has been used to improve signal to noise ratio (SNR) for signal components coherent with analysis blocks, which are time (based) subsets of acquired data used for measurement analysis. Coherent means that for each frequency component there is a constant amplitude ratio and constant relative phase with respect to a specified reference signal.

Traditionally, coherence is achieved by aligning the start of each analysis block with a meaningful reference. This reference can take different forms. For example, the reference can be an impulsive or periodic input to a test unit; the input signal may serve as an analog reference trigger to start acquiring data. This technique can be implemented by triggering an analysis block based on a reference signal. As another example, the reference may be a digital start trigger that can be fired from the measurement system or an external device. As a further example, the reference can be generated by the operating unit being monitored. This form of reference is common in areas such as machine condition monitoring where the unit is instrumented with a tachometer. It is common to instrument critical machinery with either a digital or an analog tachometer, which provides an angular reference for rotating components because the tachometer pulses at the same angular position(s) every revolution. This same tachometer can also provide an angular speed reference by measuring the frequency of tachometer pulses.

Measurement analyses may be performed on the time average of the triggered signals, or equivalently, on the vector averaged frequency spectrum. The triggering serves as a common reference for both the analysis block and the analog signal, making the analysis block fully coherent with the reference. Time synchronous averaging preserves coherent signal components and attenuates incoherent signal components, which include random noise and all other signal components with inconsistent phase incidence relative to the analysis block. In the machine condition monitoring industry, analysis blocks may be triggered based on a tachometer signal which typically pulses once per revolution. Some literature may refer to this once-per-revolution tachometer as a key phasor.

Components of the vibration signal that are integer multiples of the rotational frequency are all coherent with the triggered analysis block. Averaging allows for accurate measurement of these orders, i.e., integer multiples of the fundamental frequency. Typical rotating machinery produces a vibration signature that includes integer order components, non-integer order components including sub-harmonics, constant frequency components, and broadband vibration energy. Both integer and non-integer order components are indicative of machine components, such as bearings, gears, pulleys, etc., and of characteristic machine faults and failure modes. Thus, any individual integer or non-integer order component, or set of integer and non-integer order components, may be important indicators of machine condition, but non-integer orders will be attenuated by traditional time-synchronous averaging because they are incoherent with the analysis block. Note that triggering an analysis block does not make non-integer orders coherent with the analysis block.

Sampling in the angular (or angle) domain is another method of analyzing order components. Sampling in the angular domain can be accomplished by disciplining the sample clock with a digital tachometer signal. Another prior art approach is to perform resampling from the time domain to the angular domain in software. Resampling in software enables the use of high-precision, delta-sigma analog-to-digital converters to perform time-domain sampling. The even-angle signal can then be transformed by discrete Fourier transform (DFT) to produce an order spectrum. This order spectrum is a key industry tool for identifying vibration components that are coherent with the angular position (point in revolution). Furthermore, since the even-angle analysis block has a constant number of samples per revolution, the analysis block can be configured for the desired order resolution. Root mean square (RMS) averaging can make it easier to identify order components by reducing variance in the noise of the order spectrum. However, resampling does not remove broadband energy; nor does RMS averaging improve SNR to enable early detection of low-amplitude order components.

Note that for constant speed machinery, the frequency spectrum can be converted to an order spectrum by simple scaling of the x-axis by the inverse of the fundamental frequency. Also, for the case of steady-state measurements made at constant machine speed, vector averaging on the order spectrum is equivalent to vector averaging of the frequency spectrum, which is equivalent to the spectrum of the time-averaged analysis blocks.

Vector averaging of the order spectrum improves signal-to-noise ratio, but must also be used with extreme care because vector averaging effectively attenuates all signal components that are incoherent with the analysis block. Broadband energy, as well as non-integer multiples of the rotational frequency, are attenuated by vector averaging of frequency/order spectra. One challenge with traditional time-synchronous averaging and frequency-domain vector averaging techniques is that these techniques cannot be used to simultaneously resolve integer orders and non-integer orders of the reference frequency.

Graphical programming has become a powerful tool available to programmers. Graphical programming environments such as the National Instruments LabVIEW® product have become very popular. Tools such as Lab VIEW® have greatly increased the productivity of programmers, and increasing numbers of programmers are using graphical programming environments to develop their software applications. In particular, graphical programming tools are being used for test and measurement, data acquisition, process control, human machine interface (HMI), supervisory control and data acquisition (SCADA) applications, modeling, simulation, image processing/machine vision applications, and motion control, among others.

### SUMMARY OF THE INVENTION

Various embodiments of a system and method for frequency referenced vector averaging of machine condition signals and use in machine condition monitoring, e.g., of rotational machinery, are presented below.

In one embodiment, an analog signal may be acquired, e.g., by a DAQ device or system, resulting in a first (digitized) signal. For example, the analog signal may result from measurement of a specified parameter indicative of machine condition of an operating machine, e.g., a vibration signal, by a sensor, e.g., an accelerometer. It should be noted that in various embodiments, the analog signal may reflect vibration, voltage, current, pressure, or any other parameter of the machine being monitored from which machine condition may be determined. The first (digitized) signal includes a plurality of analysis blocks, e.g., a first plurality of analysis blocks, which, as noted above, are time (based) subsets of acquired data used for measurement analysis. In some embodiment, at least some of the analog signals may be from sensors measuring homogeneous or heterogeneous parameters indicative of machine condition.

A current analysis block may be selected. A complex valued frequency spectrum (which includes magnitude and phase) of the analysis block may be determined, e.g., computed, e.g., via DFT. At least one reference frequency (or FOI) may be specified. The at least one FOI may be specified based on characteristic machine and fault frequencies, e.g., which may be identified based on past operation of the machine or of other similar machines.

A complex valued phase compensation vector may be constructed which preserves magnitude while adjusting phase to achieve coherence between the reference frequency component and the analysis block. The complex frequency spectrum may be phase compensated by multiplying the complex-valued phase compensation vector with the complex-valued frequency spectrum of the analysis block.

If there are more analysis blocks to process, the method returns to 604 and proceeds as described above. If there are no further analysis blocks to process, the method continues as follows:

The phase compensated complex frequency spectra of the plurality of analysis blocks may be vector averaged to improve SNR at one or more specified reference frequencies. This vector averaging of phase compensated complex frequency spectra is referred to herein as phase adjusted (or compensated) frequency referenced vector averaging, and is particularly useful for machine condition monitoring, although this technique is also contemplated for use in other application domains, as well, e.g., automatic speed detection.

Reference frequency components in the averaged spectrum may be identified (i.e., measured or determined), thereby generating average reference frequency components. The average reference frequency components may be analyzed to determine machine condition.

In some embodiments, determining a phase compensated complex frequency spectrum for each analysis block includes, for each specified reference frequency: determining at least one frequency bin within a frequency range centered at the reference frequency. Phase compensating the complex valued frequency spectrum of the analysis block may include, for each specified reference frequency: multiplying the complex valued phase compensation vector with components in the at least one frequency bin, thereby adjusting the at least one frequency bin to a specified constant phase reference value. Note that in various embodiments, the frequency range may be specified by user input, or calculated according to one or more parameters of a time-domain window applied prior to the DFT.

Thus, embodiments of the above techniques may provide for improved machine condition monitoring.

### BRIEF DESCRIPTION OF THE DRAWINGS

A better understanding of the present invention can be obtained when the following detailed description of the preferred embodiment is considered in conjunction with the following drawings, in which:

FIG. 1A illustrates an exemplary system configured to implement embodiments of the present invention;

FIG. 1B illustrates an exemplary network system comprising two or more computer systems configured to implement an embodiment of the present invention;

FIG. 2A illustrates an instrumentation control system according to one embodiment of the invention;

FIG. 2B illustrates an industrial automation system according to one embodiment of the invention;

FIG. 3A is a high level block diagram of an exemplary system which may execute or utilize graphical programs;

FIG. 3B illustrates an exemplary system which may perform control and/or simulation functions utilizing graphical programs;

FIG. 4 is an exemplary block diagram of the computer systems of FIGS. 1A, 1B, 2A and 2B and 3B;

FIGS. 5A and 5B are exemplary plots of machine condition monitoring signals respectively illustrating no averaging vs. RMS averaging, and no averaging vs. traditional vector averaging vs. frequency referenced vector averaging, according to one embodiment;

FIG. 6 is a flowchart diagram illustrating one embodiment of a method for machine condition monitoring;

FIGS. 7A and 7B illustrate an exemplary phase model and graphical program implementing an exemplary embodiment, respectively, of the present techniques with respect to a list of reference frequencies where the phase is modeled constant within advanced span of each reference frequency and is neither modeled nor adjusted between reference frequencies;

FIG. 8 illustrates an exemplary graphical program implementing an exemplary embodiment of the present techniques with respect to a reference speed and orders;

FIG. 9 illustrates an exemplary plot illustrating frequency referenced averaging for low amplitude harmonics, according to one embodiment;

FIG. 10A illustrates an exemplary phase model, according to one embodiment of the present techniques with respect to a fundamental frequency and integer harmonics where the phase model shows constant phase at the fundamental and harmonic frequencies while respecting a linear phase model whose slope is determined by the measured phase of the fundamental frequency component; and

FIG. 10B illustrates an exemplary graphical program implementing an embodiment of the present techniques with respect to a reference frequency with harmonics.

While the invention is amenable to various modifications and alternative forms, specific embodiments thereof are shown by way of example in the drawings and are herein described in detail. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims.

### DETAILED DESCRIPTION OF THE INVENTION

### Incorporation by Reference

The following references are hereby incorporated by reference in their entirety as though fully and completely set forth herein:

U.S. Provisional Application Ser. No. 62/135,599, titled “Machine Condition Monitoring Using Phase Adjusted Frequency Referenced Vector Averaging”, filed Mar. 19, 2015.

U.S. Pat. No. 4,914,568 titled “Graphical System for Modeling a Process and Associated Method,” issued on Apr. 3, 1990.

U.S. Pat. No. 5,481,741 titled “Method and Apparatus for Providing Attribute Nodes in a Graphical Data Flow Environment”.

U.S. Pat. No. 6,173,438 titled “Embedded Graphical Programming System” filed Aug. 18, 1997.

U.S. Pat. No. 6,219,628 titled “System and Method for Configuring an Instrument to Perform Measurement Functions Utilizing Conversion of Graphical Programs into Hardware Implementations,” filed Aug. 18, 1997.

U.S. Pat. No. 7,210,117 titled “System and Method for Programmatically Generating a Graphical Program in Response to Program Information,” filed Dec. 20, 2000.

U.S. Pat. No. 6,965,068, titled “System and Method for Estimating Tones in an Input Signal”, filed Dec. 27, 2000.

U.S. Pat. No. 6,775,629, titled “System and Method for Estimating One or More Tones in an Input Signal”, filed Jun. 12, 2001.

U.S. Pat. No. 7,124,042, titled “System and Method for Estimating A Plurality of Tones in an Input Signal”, filed Jan. 15, 2004.

### Terms

The following is a glossary of terms used in the present application:

Memory Medium—Any of various types of non-transitory computer accessible memory devices or storage devices. The term “memory medium” is intended to include an installation medium, e.g., a CD-ROM, floppy disks 104, or tape device; a computer system memory or random access memory such as DRAM, DDR RAM, SRAM, EDO RAM, Rambus RAM, etc.; a non-volatile memory such as a Flash, magnetic media, e.g., a hard drive, or optical storage; registers, or other similar types of memory elements, etc. The memory medium may comprise other types of non-transitory memory as well or combinations thereof. In addition, the memory medium may be located in a first computer in which the programs are executed, or may be located in a second different computer which connects to the first computer over a network, such as the Internet. In the latter instance, the second computer may provide program instructions to the first computer for execution. The term “memory medium” may include two or more memory mediums which may reside in different locations, e.g., in different computers that are connected over a network.

Carrier Medium—a memory medium as described above, as well as a physical transmission medium, such as a bus, network, and/or other physical transmission medium that conveys signals such as electrical, electromagnetic, or digital signals.

Programmable Hardware Element—includes various hardware devices comprising multiple programmable function blocks connected via a programmable interconnect. Examples include FPGAs (Field Programmable Gate Arrays), PLDs (Programmable Logic Devices), FPOAs (Field Programmable Object Arrays), and CPLDs (Complex PLDs). The programmable function blocks may range from fine grained (combinatorial logic or look up tables) to coarse grained (arithmetic logic units or processor cores). A programmable hardware element may also be referred to as “reconfigurable logic”.

Software Program—the term “software program” is intended to have the full breadth of its ordinary meaning, and includes any type of program instructions, code, script and/or data, or combinations thereof, that may be stored in a memory medium and executed by a processor. Exemplary software programs include programs written in text-based programming languages, such as C, C++, PASCAL, FORTRAN, COBOL, JAVA, assembly language, etc.; graphical programs (programs written in graphical programming languages); assembly language programs; programs that have been compiled to machine language; scripts; and other types of executable software. A software program may comprise two or more software programs that interoperate in some manner. Note that various embodiments described herein may be implemented by a computer or software program. A software program may be stored as program instructions on a memory medium.

Hardware Configuration Program—a program, e.g., a netlist or bit file, that can be used to program or configure a programmable hardware element.

Program - the term “program” is intended to have the full breadth of its ordinary meaning. The term “program” includes 1) a software program which may be stored in a memory and is executable by a processor or 2) a hardware configuration program useable for configuring a programmable hardware element.

Graphical Program—A program comprising a plurality of interconnected nodes or icons, wherein the plurality of interconnected nodes or icons visually indicate functionality of the program. The interconnected nodes or icons are graphical source code for the program. Graphical function nodes may also be referred to as blocks.

The following provides examples of various aspects of graphical programs. The following examples and discussion are not intended to limit the above definition of graphical program, but rather provide examples of what the term “graphical program” encompasses:

The nodes in a graphical program may be connected in one or more of a data flow, control flow, and/or execution flow format. The nodes may also be connected in a “signal flow” format, which is a subset of data flow.

Exemplary graphical program development environments which may be used to create graphical programs include Lab VIEW®, DASYLab™, DIAdem™ and MATRIXx™/SystemBuild™ from National Instruments Corporation, Simulink® from the MathWorks, VEE™ from Agilent, WiT™ from Coreco, Vision Program Manager™ from PPT Vision, SoftWIRE™ from Measurement Computing, Sanscript™ from Northwoods Software, Khoros™ from Khoral Research, SnapMaster™ from HEM Data, VisSim™ from Visual Solutions, ObjectBench™ by SES (Scientific and Engineering Software), and VisiDAQ™ from Advantech, among others.

The term “graphical program” includes models or block diagrams created in graphical modeling environments, wherein the model or block diagram comprises interconnected blocks (i.e., nodes) or icons that visually indicate operation of the model or block diagram; exemplary graphical modeling environments include Simulink®, SystemBuild™, VisSim™, Hypersignal Block Diagram™, etc.

A graphical program may be represented in the memory of the computer system as data structures and/or program instructions. The graphical program, e.g., these data structures and/or program instructions, may be compiled or interpreted to produce machine language that accomplishes the desired method or process as shown in the graphical program.

Input data to a graphical program may be received from any of various sources, such as from a device, unit under test, a process being measured or controlled, another computer program, a database, or from a file. Also, a user may input data to a graphical program or virtual instrument using a graphical user interface, e.g., a front panel.

A graphical program may optionally have a GUI associated with the graphical program. In this case, the plurality of interconnected blocks or nodes are often referred to as the block diagram portion of the graphical program.

Node—In the context of a graphical program, an element that may be included in a graphical program. The graphical program nodes (or simply nodes) in a graphical program may also be referred to as blocks. A node may have an associated icon that represents the node in the graphical program, as well as underlying code and/or data that implements functionality of the node. Exemplary nodes (or blocks) include function nodes, sub-program nodes, terminal nodes, structure nodes, etc. Nodes may be connected together in a graphical program by connection icons or wires.

Data Flow Program—A Software Program in which the program architecture is that of a directed graph specifying the flow of data through the program, and thus functions execute whenever the necessary input data are available. Said another way, data flow programs execute according to a data flow model of computation under which program functions are scheduled for execution in response to their necessary input data becoming available. Data flow programs can be contrasted with procedural programs, which specify an execution flow of computations to be performed. As used herein “data flow” or “data flow programs” refer to “dynamically-scheduled data flow” and/or “statically-defined data flow”.

Graphical Data Flow Program (or Graphical Data Flow Diagram)—A Graphical Program which is also a Data Flow Program. A Graphical Data Flow Program comprises a plurality of interconnected nodes (blocks), wherein at least a subset of the connections among the nodes visually indicate that data produced by one node is used by another node. A Lab VIEW® VI is one example of a graphical data flow program. A Simulink block diagram is another example of a graphical data flow program.

Graphical User Interface—this term is intended to have the full breadth of its ordinary meaning. The term “Graphical User Interface” is often abbreviated to “GUI”. A GUI may comprise only one or more input GUI elements, only one or more output GUI elements, or both input and output GUI elements.

The following provides examples of various aspects of GUIs. The following examples and discussion are not intended to limit the ordinary meaning of GUI, but rather provide examples of what the term “graphical user interface” encompasses:

A GUI may comprise a single window having one or more GUI Elements, or may comprise a plurality of individual GUI Elements (or individual windows each having one or more GUI Elements), wherein the individual GUI Elements or windows may optionally be tiled together.

A GUI may be associated with a graphical program. In this instance, various mechanisms may be used to connect GUI Elements in the GUI with nodes in the graphical program. For example, when Input Controls and Output Indicators are created in the GUI, corresponding nodes (e.g., terminals) may be automatically created in the graphical program or block diagram. Alternatively, the user can place terminal nodes in the block diagram which may cause the display of corresponding GUI Elements front panel objects in the GUI, either at edit time or later at run time. As another example, the GUI may comprise GUI Elements embedded in the block diagram portion of the graphical program.

Front Panel—A Graphical User Interface that includes input controls and output indicators, and which enables a user to interactively control or manipulate the input being provided to a program, and view output of the program, while the program is executing.

A front panel is a type of GUI. A front panel may be associated with a graphical program as described above.

In an instrumentation application, the front panel can be analogized to the front panel of an instrument. In an industrial automation application the front panel can be analogized to the HMI (Human Machine Interface) of a device. The user may adjust the controls on the front panel to affect the input and view the output on the respective indicators.

Graphical User Interface Element—an element of a graphical user interface, such as for providing input or displaying output. Exemplary graphical user interface elements comprise input controls and output indicators.

Input Control—a graphical user interface element for providing user input to a program. An input control displays the value input by the user and is capable of being manipulated at the discretion of the user. Exemplary input controls comprise dials, knobs, sliders, input text boxes, etc.

Output Indicator—a graphical user interface element for displaying output from a program. Exemplary output indicators include charts, graphs, gauges, output text boxes, numeric displays, etc. An output indicator is sometimes referred to as an “output control”.

Computer System—any of various types of computing or processing systems, including a personal computer system (PC), mainframe computer system, workstation, network appliance, Internet appliance, personal digital assistant (PDA), television system, grid computing system, or other device or combinations of devices. In general, the term “computer system” can be broadly defined to encompass any device (or combination of devices) having at least one processor that executes instructions from a memory medium.

Measurement Device—includes instruments, data acquisition devices, smart sensors, and any of various types of devices that are configured to acquire and/or store data. A measurement device may also optionally be further configured to analyze or process the acquired or stored data. Examples of a measurement device include an instrument, such as a traditional stand-alone “box” instrument, a computer-based instrument (instrument on a card) or external instrument, a data acquisition card, a device external to a computer that operates similarly to a data acquisition card, a smart sensor, one or more DAQ or measurement cards or modules in a chassis, an image acquisition device, such as an image acquisition (or machine vision) card (also called a video capture board) or smart camera, a motion control device, a robot having machine vision, and other similar types of devices. Exemplary “stand-alone” instruments include oscilloscopes, multimeters, signal analyzers, arbitrary waveform generators, spectroscopes, and similar measurement, test, or automation instruments.

A measurement device may be further configured to perform control functions, e.g., in response to analysis of the acquired or stored data. For example, the measurement device may send a control signal to an external system, such as a motion control system or to a sensor, in response to particular data. A measurement device may also be configured to perform automation functions, i.e., may receive and analyze data, and issue automation control signals in response.

Functional Unit (or Processing Element)—refers to various elements or combinations of elements. Processing elements include, for example, circuits such as an ASIC (Application Specific Integrated Circuit), portions or circuits of individual processor cores, entire processor cores, individual processors, programmable hardware devices such as a field programmable gate array (FPGA), and/or larger portions of systems that include multiple processors, as well as any combinations thereof

Automatically—refers to an action or operation performed by a computer system (e.g., software executed by the computer system) or device (e.g., circuitry, programmable hardware elements, ASICs, etc.), without user input directly specifying or performing the action or operation. Thus the term “automatically” is in contrast to an operation being manually performed or specified by the user, where the user provides input to directly perform the operation. An automatic procedure may be initiated by input provided by the user, but the subsequent actions that are performed “automatically” are not specified by the user, i.e., are not performed “manually”, where the user specifies each action to perform. For example, a user filling out an electronic form by selecting each field and providing input specifying information (e.g., by typing information, selecting check boxes, radio selections, etc.) is filling out the form manually, even though the computer system must update the form in response to the user actions. The form may be automatically filled out by the computer system where the computer system (e.g., software executing on the computer system) analyzes the fields of the form and fills in the form without any user input specifying the answers to the fields. As indicated above, the user may invoke the automatic filling of the form, but is not involved in the actual filling of the form (e.g., the user is not manually specifying answers to fields but rather they are being automatically completed). The present specification provides various examples of operations being automatically performed in response to actions the user has taken.

Concurrent—refers to parallel execution or performance, where tasks, processes, or programs are performed in an at least partially overlapping manner. For example, concurrency may be implemented using “strong” or strict parallelism, where tasks are performed (at least partially) in parallel on respective computational elements, or using “weak parallelism”, where the tasks are performed in an interleaved manner, e.g., by time multiplexing of execution threads.

Wireless—refers to a communications, monitoring, or control system in which electromagnetic or acoustic waves carry a signal through space rather than along a wire.

Approximately—refers to a value being within some specified tolerance or acceptable margin of error or uncertainty of a target value, where the specific tolerance or margin is generally dependent on the application. Thus, for example, in various applications or embodiments, the term approximately may mean: within 0.1% of the target value, within 0.2% of the target value, within 0.5% of the target value, within 1%, 2%, 5%, or 10% of the target value, and so forth, as required by the particular application of the present techniques.

Advanced Span (Hz)—specifies a frequency span centered at an identified reference frequency (or frequency of interest), e.g., fundamental frequency, of a signal in which noise and spurious components are ignored for the measurement as it is assumed that the magnitudes and phases of the frequency spectrum are dominated by the magnitude and phase of the associated reference frequency at the fourth order of the fan speed.

Reference Frequency—refers to a frequency of interest. A reference frequency may be determined based on machine running speed, component geometry, structural resonances, typical and historical failure frequencies, and/or measurement.

Reference Frequency Component—refers to an identified (measured) frequency, amplitude, and phase of a signal component where the frequency is within the advanced span of the specified reference frequency.

Fundamental Reference Frequency Component—refers to an identified (measured) frequency, amplitude, and phase of a fundamental signal component. The frequency of the fundamental reference frequency component can be used as a primary measurement of frequency for all harmonics. The phase of the fundamental reference frequency component determines the slope of the phase model when using a linear phase model appropriate for a fundamental reference frequency component and harmonics.

Harmonic—refers to a signal component where the frequency of the harmonic frequency component is a constant multiple of the frequency of a fundamental reference frequency component. Harmonic can also refer to the frequency ratio between a harmonic frequency component and a fundamental reference frequency component.

Order—refers to the ratio between a frequency and a first, fundamental, reference frequency, such as the operating rotational speed of a machine. For example, a fan with four blades will necessarily have a blade-pass frequency at the fourth order of the fan speed.

Order Spectrum—refers to frequency components in units of cycles/revolution, i.e., multiples of a reference frequency, instead of Hz. In other words, the frequency components of a signal are presented in terms of signal magnitude at multiples of a reference frequency, i.e., orders, and so a signal magnitude (y-axis) at position 1 on the x-axis indicates the first order. Similarly, the value of the signal at (order) 2 is the signal magnitude of the component (twice the reference frequency). Note that the order spectrum is not limited to components at integer order values.

Analysis Block—refers to a subset of acquired/sampled data used for measurement analysis.

Data Acquisition (DAQ)—refers to the process of measuring an electrical or physical phenomenon such as vibration, voltage, current, temperature, pressure, or sound with a computer. A DAQ system typically includes sensors, DAQ measurement hardware, and a computer with programmable software.

Component Phase—refers to the measured phase of a sinusoidal component. The phase is measured relative to a reference sine wave at the same frequency where the reference phase is zero indicating the reference sinusoid has a value of zero and positive slope.

Phase Adjustment—refers to a mathematical operation used to shift the phase of a specific frequency component without changing the magnitude. For a complex-valued function the phase adjustment operation is equivalent to a multiplication by e^{iθ}, where θ is the amount of the adjustment.

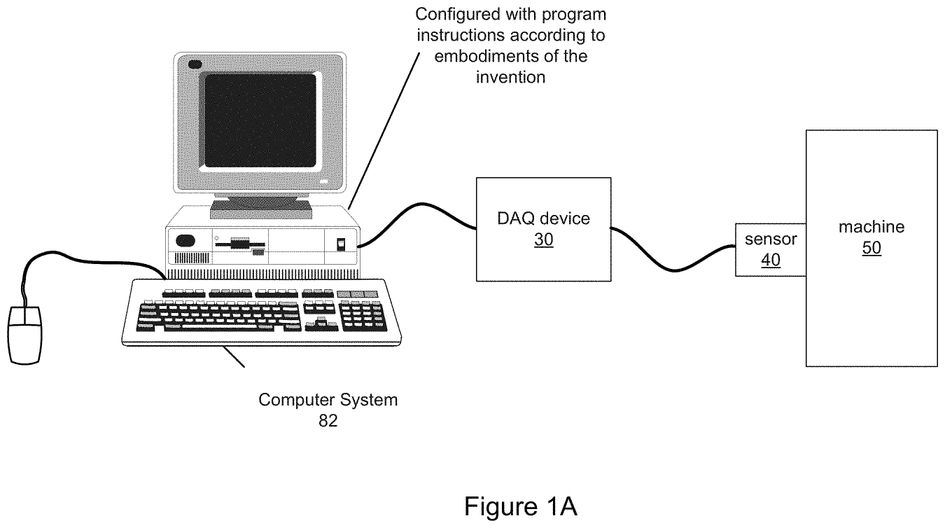

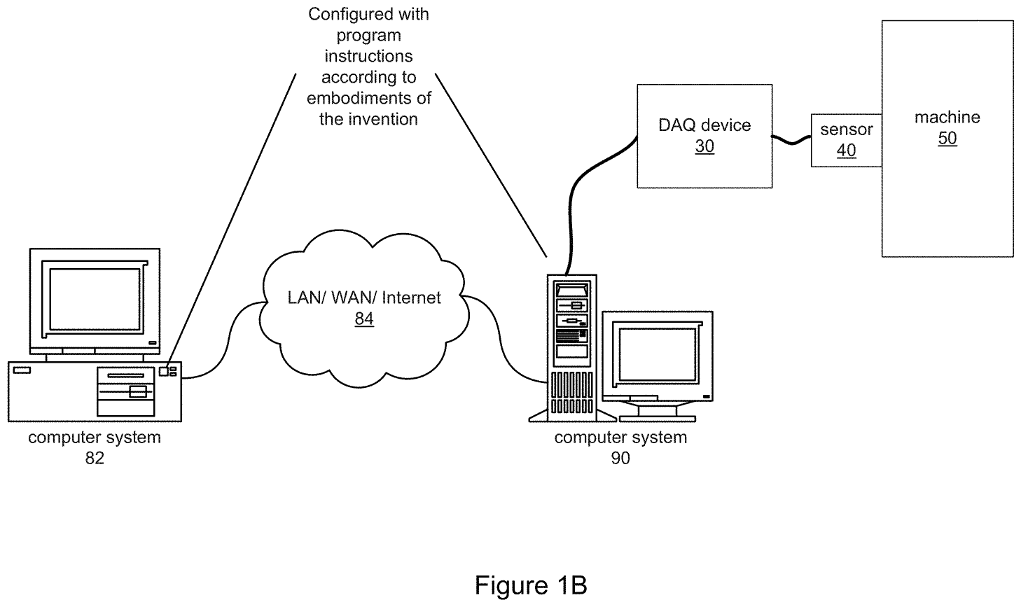

### FIG. 1A—Exemplary System

FIG. 1A illustrates an exemplary system configured to implement embodiments of the present techniques. The exemplary system includes a computer system 82, coupled to a data acquisition (DAQ) device 30, which is itself coupled to a sensor 40, e.g., an accelerometer, which is configured to measure some parameter of a machine 50.

As shown in FIG. 1A, the computer system 82 may include a display device, e.g., configured to display a program implementing an embodiment of the present invention, e.g., a graphical program, as the program is created and/or executed. The display device may also be configured to display a graphical user interface or front panel of the program during execution of the program. The graphical user interface may comprise any type of graphical user interface, e.g., depending on the computing platform.

The computer system 82 may include at least one memory medium on which one or more computer programs or software components according to one embodiment of the present invention may be stored. For example, the memory medium may store one or more graphical programs which are executable to perform the methods described herein. Additionally, the memory medium may store a graphical programming development environment application used to create and/or execute such graphical programs. The memory medium may also store operating system software, as well as other software for operation of the computer system. Various embodiments further include receiving or storing instructions and/or data implemented in accordance with the foregoing description upon a carrier medium.

Note that in various embodiments, the sensor may be any type of sensor appropriate for the application. Thus, while accelerometers, velocimeters, and proximity probes are common sensors used for machine monitoring, e.g., for vibration analysis, other sensors contemplated include, but are not limited to, magnetometers, pressure sensors, voltage sensors, current sensors, and so forth. In other words, any type of sensors may be used as desired, depending on the application.

### FIG. 1B—Networked System

FIG. 1B illustrates an exemplary networked system configured to implement embodiments of the present techniques. As may be seen, in the embodiment shown, the system includes a first computer system 82 that is coupled to a second computer system 90, where the second computer system is coupled to the DAQ device 30 and sensor 40 of FIG. 1A. The computer system 82 may be coupled via a network 84 (or a computer bus) to the second computer system 90. The computer systems 82 and 90 may each be any of various types, as desired. The network 84 can also be any of various types, including a LAN (local area network), WAN (wide area network), the Internet, or an Intranet, among others. The computer systems 82 and 90 may execute a program, e.g., a graphical program, in a distributed fashion. For example, computer 82 may execute a first portion of the block diagram of a graphical program and computer system 90 may execute a second portion of the block diagram of the graphical program. As another example, computer 82 may display the graphical user interface of a graphical program and computer system 90 may execute the block diagram of the graphical program.

In one embodiment, the graphical user interface of the graphical program may be displayed on a display device of the computer system 82, and the block diagram may execute on a device coupled to the computer system 82. The device may include a programmable hardware element and/or may include a processor and memory medium which may execute a real time operating system. In one embodiment, the graphical program may be downloaded and executed on the device. For example, an application development environment with which the graphical program is associated may provide support for downloading a graphical program for execution on the device in a real time system.

It should be noted that in further embodiments, the computer 82 may be coupled to the DAQ device 30 over the network 84, and the second computer system 90 may be omitted. Other network connection schemes may be used as desired, as the present techniques do not require any particular connection topology.

### Further Exemplary Systems

While embodiments of the present invention are particularly suitable for machine condition monitoring, various other embodiments may be involved with performing test and/or measurement functions; controlling and/or modeling instrumentation or industrial automation hardware; modeling and simulation functions, e.g., modeling or simulating a device or product being developed or tested, etc. Exemplary test applications where the graphical program may be used include hardware-in-the-loop testing and rapid control prototyping, among others.

However, it is noted that embodiments of the present invention can be used for a plethora of applications and is not limited to the above applications. In other words, applications discussed in the present description are exemplary only, and embodiments of the present invention may be used in any of various types of systems. Thus, embodiments of the system and method of the present invention is configured to be used in any of various types of applications, including the control of other types of devices such as multimedia devices, video devices, audio devices, telephony devices, Internet devices, etc., as well as general purpose software applications such as word processing, spreadsheets, network control, network monitoring, financial applications, games, etc.

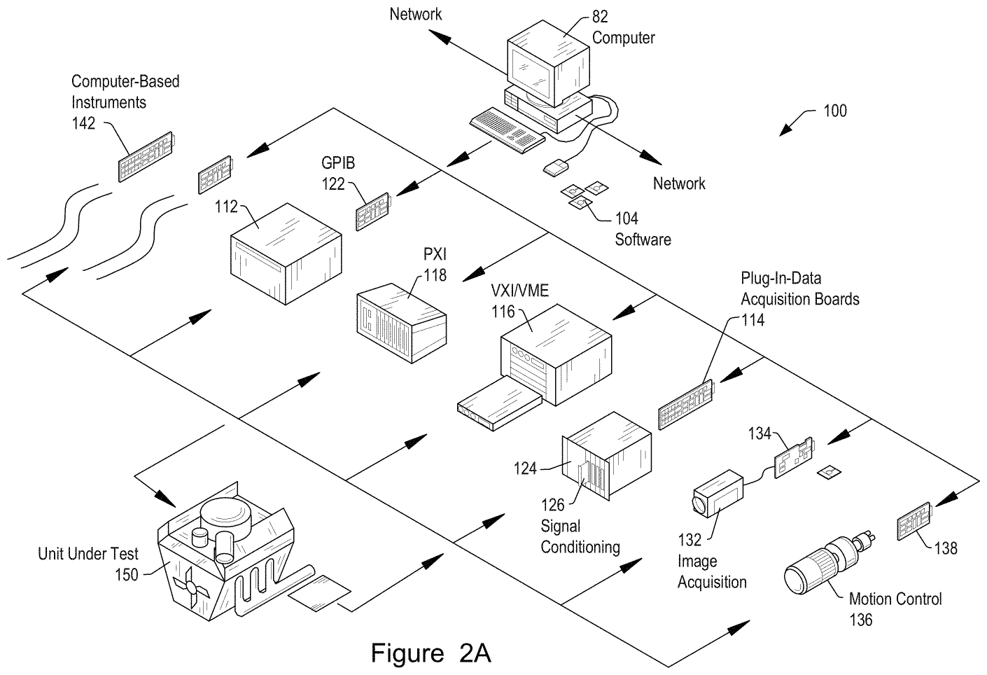

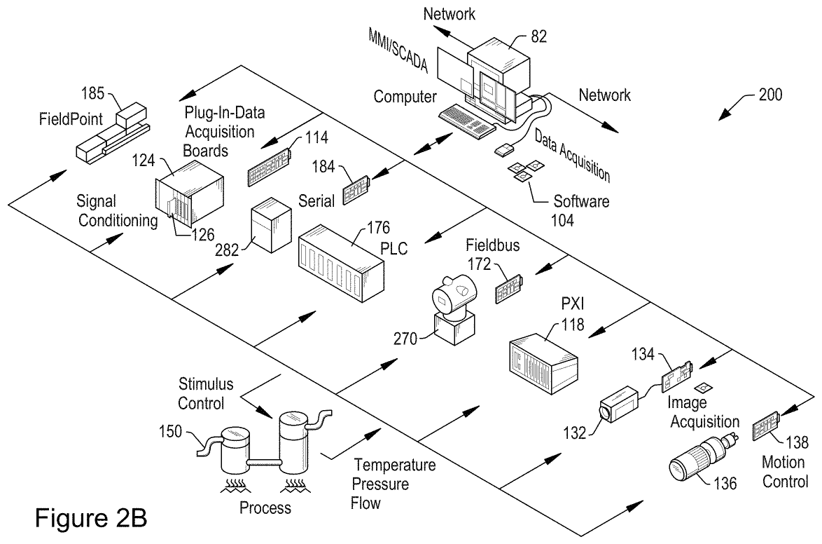

FIG. 2A illustrates an exemplary instrumentation control system 100 which may implement embodiments of the invention. The system 100 comprises a host computer 82 which couples to one or more instruments. The host computer 82 may comprise a CPU, a display screen, memory, and one or more input devices such as a mouse or keyboard as shown. The computer 82 may operate with the one or more instruments to analyze, measure or control a unit under test (UUT) or process 150, e.g., via execution of software 104.

The one or more instruments may include a GPIB instrument 112 and associated GPIB interface card 122, a data acquisition board 114 inserted into or otherwise coupled with chassis 124 with associated signal conditioning circuitry 126, a VXI instrument 116, a PXI instrument 118, a video device or camera 132 and associated image acquisition (or machine vision) card 134, a motion control device 136 and associated motion control interface card 138, and/or one or more computer based instrument cards 142, among other types of devices. The computer system may couple to and operate with one or more of these instruments. The instruments may be coupled to the unit under test (UUT) or process 150, or may be coupled to receive field signals, typically generated by transducers. The system 100 may be used in a machine condition monitoring, data acquisition and control application, in a test and measurement application, an image processing or machine vision application, a process control application, a man-machine interface application, a simulation application, or a hardware-in-the-loop validation application, among others.

FIG. 2B illustrates an exemplary industrial automation system 200 which may implement embodiments of the invention. The industrial automation system 200 is similar to the instrumentation or test and measurement system 100 shown in FIG. 2A. Elements which are similar or identical to elements in FIG. 2A have the same reference numerals for convenience. The system 200 may comprise a computer 82 which couples to one or more devices or instruments. The computer 82 may comprise a CPU, a display screen, memory, and one or more input devices such as a mouse or keyboard as shown. The computer 82 may operate with the one or more devices to perform an automation function (with machine condition monitoring) with respect to a process or device 150, such as HMI (Human Machine Interface), SCADA (Supervisory Control and Data Acquisition), portable or distributed data acquisition, process control, advanced analysis, or other control, among others, e.g., via execution of software 104.

The one or more devices may include a data acquisition board 114 inserted into or otherwise coupled with chassis 124 with associated signal conditioning circuitry 126, a PXI instrument 118, a video device 132 and associated image acquisition card 134, a motion control device 136 and associated motion control interface card 138, a fieldbus device 270 and associated fieldbus interface card 172, a PLC (Programmable Logic Controller) 176, a serial instrument 282 and associated serial interface card 184, or a distributed data acquisition system, such as Fieldpoint system 185, available from National Instruments Corporation, among other types of devices.

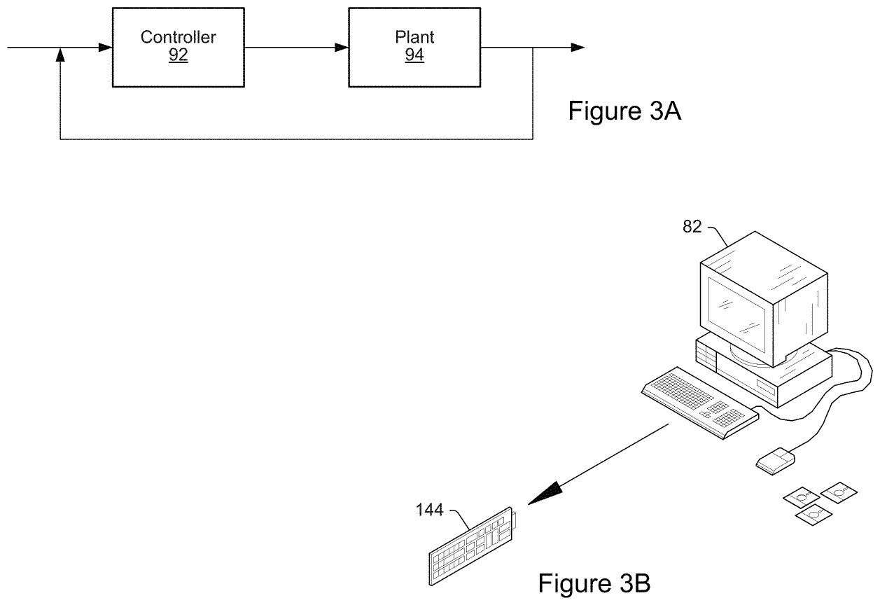

FIG. 3A is a high level block diagram of an exemplary system which may execute or utilize graphical programs implementing an embodiment of the present techniques. FIG. 3A illustrates a general high-level block diagram of a generic control and/or simulation system which comprises a controller 92 and a plant 94. The controller 92 represents a control system/algorithm the user may be trying to develop. The plant 94 represents the system the user may be trying to control. For example, if the user is designing an ECU for a car, the controller 92 is the ECU and the plant 94 is the car's engine (and possibly other components such as transmission, brakes, and so on.) As shown, a user may create a graphical program that specifies or implements the functionality of one or both of the controller 92 and the plant 94. For example, a control engineer may use a modeling and simulation tool to create a model (graphical program) of the plant 94 and/or to create the algorithm (graphical program) for the controller 92.

FIG. 3B illustrates an exemplary system which may perform control and/or simulation functions, e.g., with machine condition monitoring. As shown, the controller 92 may be implemented by a computer system 82 or other device (e.g., including a processor and memory medium and/or including a programmable hardware element) that executes or implements a graphical program. In a similar manner, the plant 94 may be implemented by a computer system or other device 144 (e.g., including a processor and memory medium and/or including a programmable hardware element) that executes or implements a graphical program, or may be implemented in or as a real physical system, e.g., a car engine.

In one embodiment of the invention, one or more graphical programs may be created which are used in performing rapid control prototyping. Rapid Control Prototyping (RCP) generally refers to the process by which a user develops a control algorithm and quickly executes that algorithm on a target controller connected to a real system. The user may develop the control algorithm using a graphical program, and the graphical program may execute on the controller 92, e.g., on a computer system or other device. The computer system 82 may be a platform that supports real time execution, e.g., a device including a processor that executes a real time operating system (RTOS), or a device including a programmable hardware element.

In one embodiment of the invention, one or more graphical programs may be created which are used in performing Hardware in the Loop (HIL) simulation. Hardware in the Loop (HIL) refers to the execution of the plant model 94 in real time to test operation of a real controller 92. For example, once the controller 92 has been designed, it may be expensive and complicated to actually test the controller 92 thoroughly in a real plant, e.g., a real car. Thus, the plant model (implemented by a graphical program) is executed in real time to make the real controller 92 “believe” or operate as if it is connected to a real plant, e.g., a real engine.

In the embodiments of FIGS. 2A, 2B, and 3B above, one or more of the various devices may couple to each other over a network, such as the Internet. In one embodiment, the user operates to select a target device from a plurality of possible target devices for programming or configuration using a graphical program. Thus the user may create a graphical program on a computer and use (execute) the graphical program on that computer or deploy the graphical program to a target device (for remote execution on the target device) that is remotely located from the computer and coupled to the computer through a network.

Graphical software programs which perform data acquisition, analysis and/or presentation, e.g., for measurement, instrumentation control, industrial automation, modeling, or simulation, such as in the applications shown in FIGS. 2A and 2B, may be referred to as virtual instruments.

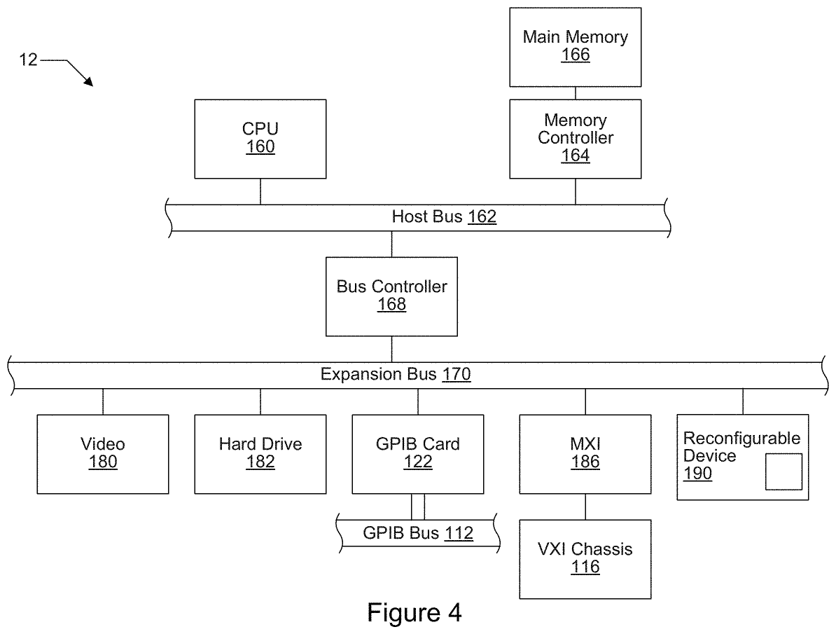

### FIG. 4—Computer System Block Diagram

FIG. 4 is a block diagram 12 representing one embodiment of the computer system 82 and/or 90 illustrated in FIGS. 1A and 1B, or computer system 82 shown in FIGS. 2A or 2B. It is noted that any type of computer system configuration or architecture can be used as desired, and FIG. 4 illustrates a representative PC embodiment. It is also noted that the computer system may be a general purpose computer system, a computer implemented on a card installed in a chassis, or other types of embodiments. Elements of a computer not necessary to understand the present description have been omitted for simplicity.

The computer may include at least one central processing unit or CPU (processor) 160 which is coupled to a processor or host bus 162. The CPU 160 may be any of various types, including an x86 processor, e.g., a Pentium class, a PowerPC processor, a CPU from the SPARC family of RISC processors, as well as others. A memory medium, typically comprising RAM and referred to as main memory, 166 is coupled to the host bus 162 by means of memory controller 164. The main memory 166 may store one or more programs implementing embodiments of the present techniques. The main memory may also store operating system software, as well as other software for operation of the computer system.

The host bus 162 may be coupled to an expansion or input/output bus 170 by means of a bus controller 168 or bus bridge logic. The expansion bus 170 may be the PCI (Peripheral Component Interconnect) expansion bus, although other bus types can be used. The expansion bus 170 includes slots for various devices such as described above. The computer 82 further comprises a video display subsystem 180 and hard drive 182 coupled to the expansion bus 170. The computer 82 may also comprise a GPIB card 122 coupled to a GPIB bus 112, and/or an MXI device 186 coupled to a VXI chassis 116.

As shown, a device 190 may also be connected to the computer. The device 190 may include a processor and memory which may execute a real time operating system. The device 190 may also or instead comprise a programmable hardware element. The computer system may be configured to deploy a program, e.g., a graphical program, to the device 190 for execution on the device 190. In graphical program embodiments, the deployed graphical program may take the form of graphical program instructions or data structures that directly represents the graphical program. Alternatively, the deployed graphical program may take the form of text code (e.g., C code) generated from the graphical program. As another example, the deployed graphical program may take the form of compiled code generated from either the graphical program or from text code that in turn was generated from the graphical program. Note, however, that in other embodiments, any kind of program may be used as desired, e.g., textual, graphical, etc.

### Overview

The present techniques extend traditional averaging techniques via explicit modeling of phase difference (which corresponds to time delay) to preserve specific frequencies.

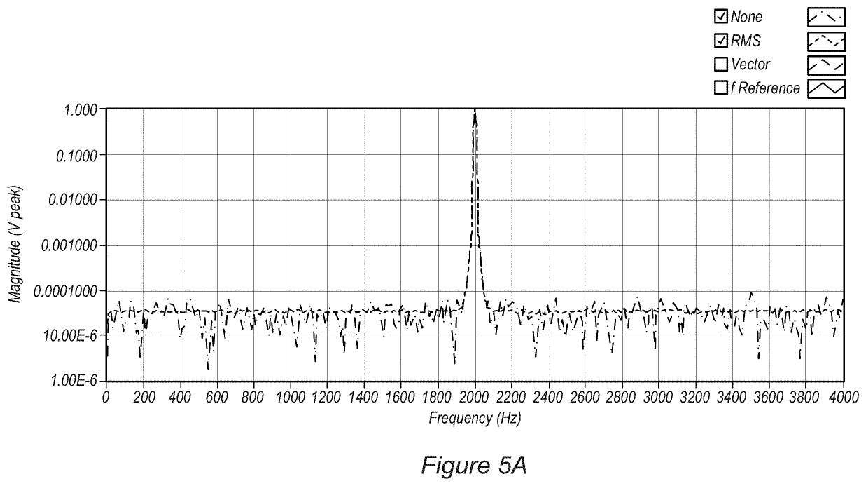

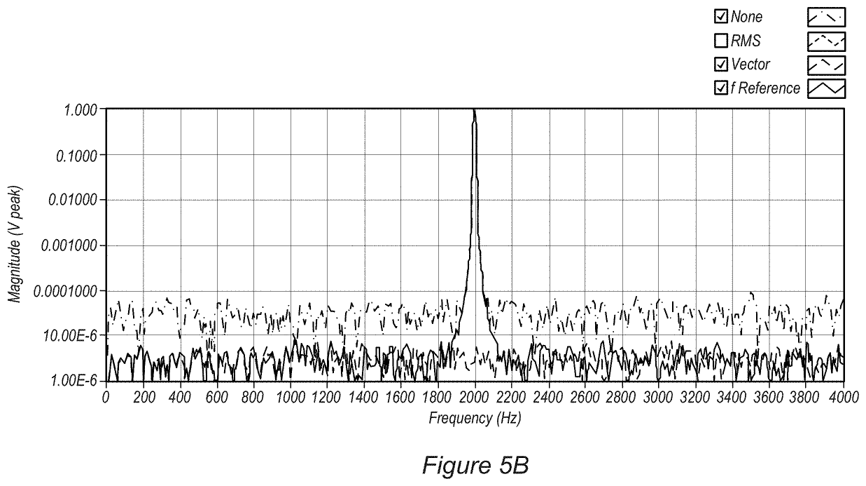

Based on characteristic machine and fault frequencies, specific frequencies may be selected as frequencies of interest (FOI), which may also be referred to as reference frequencies. At every FOI, spectral bins may be phase adjusted so that averaging at the reference frequencies preserves narrowband amplitude. In applications such as machine condition monitoring, these narrowband components may occur at expected frequencies and orders of running speed. Recall that at constant speed, scaling can be used to convert between frequency and order domains. This means that orders of interest (OOI), i.e., reference orders, can also be expressed as FOIs (frequencies of interest) and vice versa. The terms “FOIs” and “reference frequencies” are used herein to refer to specified components in the acquired signal that should be preserved through averaging. When signal to noise ratio is poor, noise energy masks (or even dominates) the spectral energy at frequencies which may compromise measurement of narrowband component amplitudes. Vector averaging can be used to attenuate incoherent noise (see FIGS. 5A and 5B, discussed below).

When averaging complex spectra, phase adjustment may be performed through complex-valued multiplication of the complex-valued frequency spectrum with a constructed phase compensation vector. The phase compensation vector is a complex-valued array where every element has magnitude 1.0 and phase calculated to adjust the phase of frequency components. Thus, the phase compensation vector may adjust frequency bins of interest to a consistent phase reference, i.e., a specified constant phase reference value, thereby making the components coherent with respect to the analysis block. The bins associated with each reference frequency may be determined by a configuration parameter referred to as advanced span, which specifies a frequency range centered at the frequency of interest; in some embodiments, by default, advanced span may be calculated according to parameters of the time-domain window applied prior to application of the discrete Fourier transform (DFT).

Embodiments of the techniques disclosed herein may operate to improve signal to noise ratio in condition monitoring applications that allows for early fault detection in rotating machinery, and may also provide more accurate identification of distortion components even in the presence of broadband noise. Another potential application of embodiments of the present techniques is in automatic speed detection, which is not reliable in prior art software products at least because order components are difficult to detect in smooth-running machines, and because not all machines exhibit the same order components. For example, in one embodiment, machine speed or changes in machine speed may be detected based at least in part on the analog signals and measured frequencies of reference frequency components at constant orders of the machine speed.

In some embodiments, the method may detect orders to track based at least in part on the analog signals and measured amplitudes of reference frequency components in the averaged phase compensated complex frequency spectra. Additionally, embodiments of the present techniques may allow less specialized hardware to be used in applications that traditionally required specialized instrumentation that supports time-synchronous averaging, i.e., embodiments of the disclosed techniques may allow for synchronous averaging of integer and non-integer orders of machine condition related signals which is not possible with traditional instrumentation.

The techniques disclosed herein may be applied to the complex valued spectra of time waveforms. Equivalently, the techniques disclosed herein may be applied to the complex valued order spectrum of even-angle signals to yield a vector averaged spectrum that preserves arbitrarily selected frequencies/orders (i.e., frequencies/orders of interest). Embodiments of the techniques disclosed herein may improve SNR, which may result in more accurate measurements of narrow-band component amplitudes and enable early detection of changes to machine condition, e.g., machine faults.

More specifically, embodiments of the present techniques may provide one or more of the following advantages or benefits over prior art approaches:

1. Leverage existing data-acquisition hardware.
a. Leverage any analog-to-digital converters because this invention does not require external, speed-dependent sampling.
b. Avoid additional cost and complexity of additional reference channels and analog input channels.
c. Leverage existing signal conditioning paths because the present techniques do not require additional digital or analog circuitry for triggering.

2. Improve signal-to-noise ratio (SNR).
a. Enable usage of set of reference frequencies including integer and non-integer order/harmonic components.
b. Use all frequency components to provide a better estimate of fundamental frequency and order/harmonic components.

3. Use existing data streams and Discrete Fourier Transform (DFT)
a. Efficiently compute phase-adjusted spectrum by modulation of the complex spectrum prior to averaging.
b. Maintain identical measurement bandwidth with existing data rate
c. Maintain identical spectral resolution with existing block duration
d. Maintain or reduce total acquisition time by processing of overlapping analysis blocks.

### FIGS. 5A and 5B—Respective Exemplary Plots of Machine Condition Monitoring Signals Illustrating No Averaging vs. RMS Averaging, and No Averaging vs. Traditional vs. Frequency Referenced Vector Averaging

FIGS. 5A and 5B are exemplary plots of machine condition monitoring signals respectively illustrating no averaging compared with RMS averaging, and traditional vector averaging compared with frequency referenced vector averaging and no averaging, according to one embodiment. As FIG. 5A illustrates, when compared to the spectrum of any one analysis block, represented by the unaveraged spectrum, labeled “None” in the legend, RMS averaging, labeled “RMS”, reduces the variance in the noise. FIG. 5B illustrates that traditional vector averaging, labeled “Vector”, attenuates noise, but also attenuates important signal components, while frequency referenced vector averaging, labeled “f Reference”, attenuates all signal components that are incoherent with the analysis block while maintaining reference frequency components in the averaged spectrum. Note that for illustration purposes, the frequency of the reference signal was selected to be incoherent with consecutive analysis blocks and such that 100 vector averages would completely attenuate the 1 V peak (0.7071 Vms) signal amplitude. As may be seen, embodiments of the present techniques may be required to preserve and accurately measure reference components.

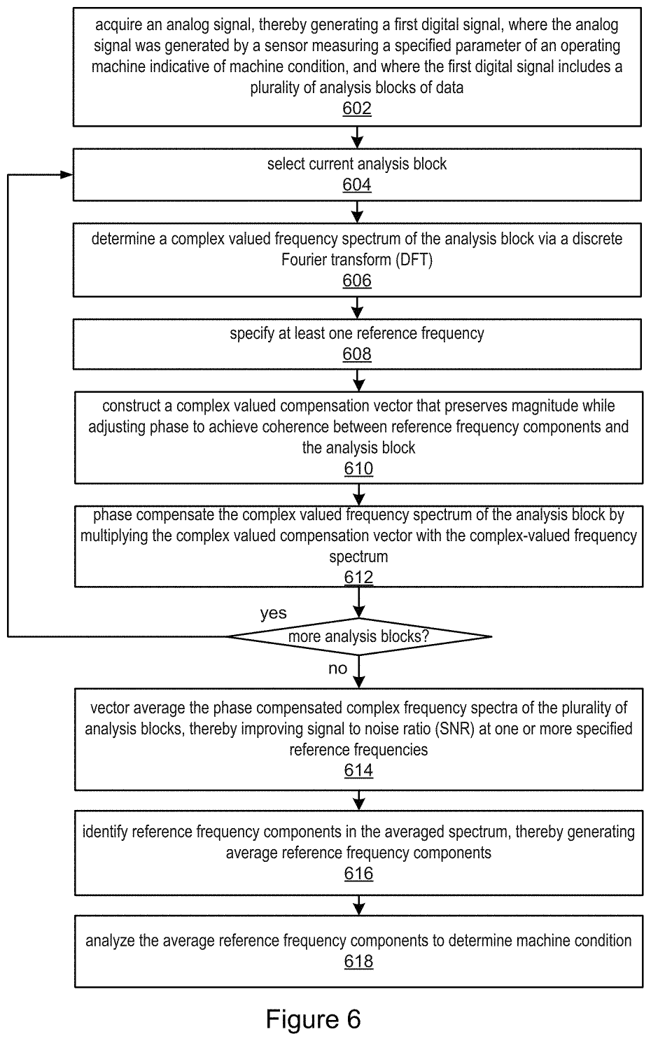

### FIG. 6—Flowchart of a Method for Machine Condition Monitoring Using Phase Adjusted Frequency Referenced Vector Averaging

FIG. 6 illustrates a method for machine condition monitoring using phase adjusted frequency referenced vector averaging, according to some embodiments. The method shown in FIG. 6 may be used in conjunction with any of the computer systems or devices shown in the above Figures, among other devices. In various embodiments, some of the method elements shown may be performed concurrently, in a different order than shown, or may be omitted. Additional method elements may also be performed as desired.

As shown, the method may operate as follows.

In 602, an analog signal may be acquired, e.g., by a DAQ device or system, resulting in a first (digitized) signal. For example, the analog signal may result from measurement of a specified parameter indicative of machine condition of an operating machine, e.g., a vibration signal, by a sensor, e.g., an accelerometer. It should be noted that in various embodiments, the analog signal may reflect vibration, voltage, current, pressure, or any other parameter of the machine being monitored from which machine condition may be determined. The first (digitized) signal includes a plurality of analysis blocks, e.g., a first plurality of analysis blocks, which, as noted above, are time (based) subsets of acquired data used for measurement analysis. In some embodiment, at least some of the analog signals may be from sensors measuring homogeneous or heterogeneous parameters indicative of machine condition.

In 604, a current analysis block may be selected.

In 606, a complex valued frequency spectrum (which includes magnitude and phase) of the analysis block may be determined, e.g., computed, e.g., via DFT.

In 608, at least one reference frequency (or FOI) may be specified. As noted above, the at least one FOI may be specified based on characteristic machine and fault frequencies, e.g., which may be identified based on past operation of the machine or of other similar machines.

In 610, a complex valued phase compensation vector may be constructed which preserves magnitude while adjusting phase to achieve coherence between the reference frequency component and the analysis block.

In 612, the complex frequency spectrum may be phase compensated by multiplying the complex-valued phase compensation vector with the complex-valued frequency spectrum of the analysis block.

As indicated in 613, if there are more analysis blocks to process, the method returns to 604 and proceeds as described above. If there are no further analysis blocks to process, the method continues to 614.

In 614, the phase compensated complex frequency spectra of the plurality of analysis blocks may be vector averaged to improve SNR at one or more specified reference frequencies. This vector averaging of phase compensated complex frequency spectra is referred to herein as phase adjusted (or compensated) frequency referenced vector averaging, and is particularly useful for machine condition monitoring, although this technique is also contemplated for use in other application domains, as well, e.g., automatic speed detection.

In 616, reference frequency components in the averaged spectrum may be identified (i.e., measured or determined), thereby generating average reference frequency components.

In 618, the average reference frequency components may be analyzed to determine machine condition.

In some embodiments, determining a phase compensated complex frequency spectrum for each analysis block includes, for each specified reference frequency: determining at least one frequency bin within a frequency range centered at the reference frequency. Phase compensating the complex valued frequency spectrum of the analysis block may include, for each specified reference frequency: multiplying the complex valued phase compensation vector with components in the at least one frequency bin, thereby adjusting the at least one frequency bin to a specified constant phase reference value.

Note that in various embodiments, the frequency range may be specified by user input, or calculated according to one or more parameters of a time-domain window applied prior to the DFT.

Thus, embodiments of the above techniques may provide for improved machine condition monitoring.

### Exemplary Embodiments

The following describes various exemplary embodiments of the method of FIG. 6, although the embodiments presented are exemplary only, and are not intended to limit the invention to any particular form or function.

### Exemplary Embodiment 1

In the following exemplary embodiment, a list of reference frequencies is provided as input, e.g., stored in a memory medium of a device, such as one of the devices discussed above, e.g., computer system 82. In one embodiment, no phase relationship is assumed between the reference frequencies. Thus, the relative time delay for each reference frequency may be modeled by the phase of the associated reference frequency component. In other words, the phase of the reference frequency component may be considered a proxy for time delay. For each bin that is within the advanced span of a reference frequency, the compensation vector may be constructed such that reference frequency bins are adjusted to a specified constant reference (phase) value, e.g., zero, for the identified reference frequency component. If the bin is outside the advanced span, the bin may not be phase compensated. As noted above, the advanced span of a reference frequency specifies a frequency span centered at an identified reference frequency (or frequency of interest) of a signal in which noise and spurious components are ignored for a measurement.

More specifically, one embodiment of the technique may operate as follows:

As noted above, a list of reference frequencies may be received.

An analog signal may be acquired via the data-acquisition system (or device), e.g., as per method element 602 above.

For each analysis block, e.g., selected as per method element 604 above:

The complex-valued frequency spectrum may be computed with via discrete Fourier transform (DFT), e.g., as per method element 606, above.

For each specified reference frequency, the (actual) frequency, amplitude, and phase of the reference frequency component at or near the specified reference frequency may be identified.

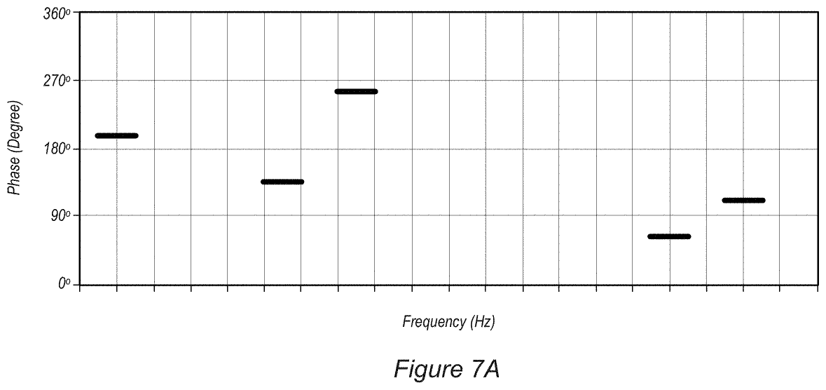

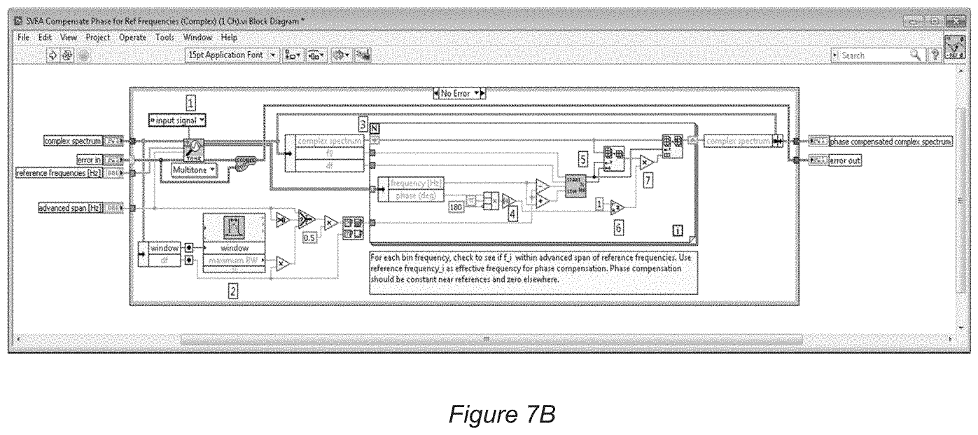

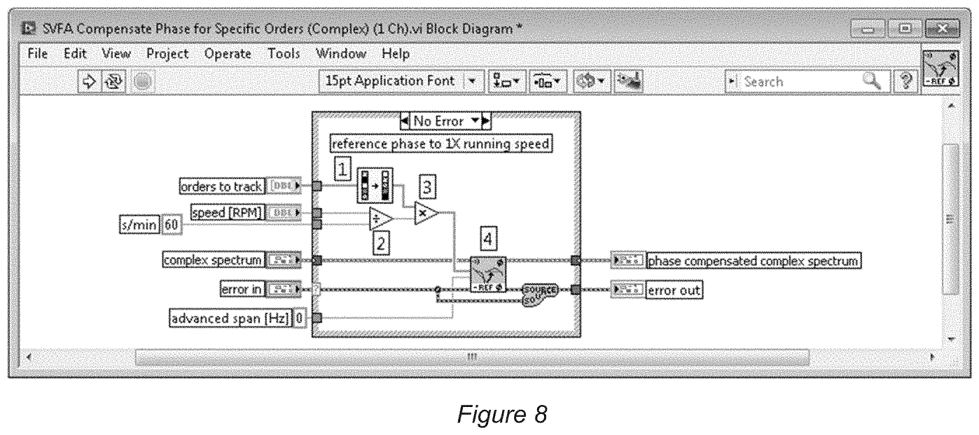

For each identified reference frequency component (at or near the specified reference frequency), the compensation vector element or portion which adjusts phase of the identified reference frequency component to a specified constant reference (phase) value, e.g., zero, may be constructed. Note that DFT bins not associated with the identified reference frequency component will not be adjusted/compensated, i.e., DFT bins not in the advanced span of the specified reference frequency of the identified reference frequency component will not be phase adjusted/compensated. An exemplary phase model for a list of reference frequencies is shown in FIG. 7A. For each analysis block, the absolute phase of each frequency component may be measured, and a phase compensation vector may be constructed in order to shift the phase of each frequency component to a specified constant phase reference value (e.g., zero) prior to vector averaging.

The complex-valued phase compensation vector, or relevant element or portion thereof, may be multiplied with the complex-valued frequency spectrum of the analysis block, thereby phase compensating the complex-valued frequency spectrum of the analysis block. As noted above, only bins in the advanced span of the specified reference frequency may be adjusted/compensated.

Once all the analysis blocks have been processed (phase adjusted/compensated), the phase-compensated frequency spectra may be vector averaged, e.g., as per method element 614 above, thereby generating a phase-adjusted frequency-referenced vector averaged spectrum.

Reference frequency components may then be identified (i.e., measured or determined) in the phase adjusted frequency referenced vector averaged spectrum, as per method element 616 above, and in some embodiment, the identified components may be analyzed to determine machine condition, e.g., as per method element 618 above.

For testing and reference, the above embodiment was implemented in a graphical programming language known as G, provided by National Instruments Corporation. FIG. 7B illustrates an exemplary graphical program implementing a version of the above embodiment with respect to a with respect to a list of reference frequencies.

Note that before calling the graphical program shown in FIG. 7B, other (e.g., graphical) programs may be used to acquire signals from data acquisition hardware, select each analysis block, compute the complex-valued frequency spectrum, and specify reference-frequency components. The exemplary graphical program of FIG. 7B is configured to perform the above described identification of frequency, amplitude, and phase of reference frequency components, construction of the compensation vector (or element/portion thereof), and phase compensation (multiplication by the compensation vector or element/portion) regarding the complex-valued frequency spectrum.

As may be seen, the program receives a complex spectrum, a set (or list) of reference frequencies (Hz), and advanced span (Hz), as input, and generates a phase compensated complex spectrum as output.

The graphical program of FIG. 7B includes indications or markers of general respective portions that perform corresponding parts of the technique described above, where the indications are integer labels 1-7 and the indicated portions generally correspond as follows:

Portion “1” (so labeled in FIG. 7B) operates to identify the reference frequency components, including frequency, amplitude, and phase.

Portion “2” calculates an advanced span if the user inputs a value less than or equal to a specified constant reference (phase) value, e.g., zero.

Portion “3” iterates through the identified reference frequency components, where, for each iteration:

Portion “4” calculates the phase adjustment required to change the reference frequency component phase to a specified constant reference (phase) value, e.g., zero.

Portion “5” retrieves the subset of the complex-valued spectrum associated with the reference frequency.

Portion “6” constructs the complex-valued compensation vector (or element/portion thereof), which is constant for each reference frequency component, with magnitude of 1 and the required phase (the phase adjustment required to adjust the phase of the reference frequency component to a specified constant reference (phase) value, e.g., zero).

Portion “7” multiplies the complex-valued compensation vector with the subset of the complex-valued frequency spectrum.

After calling the exemplary graphical program of FIG. 7B, additional programs, e.g., graphical programs, may be used to vector average the phase-compensated spectrum and analyze the average spectrum to determine machine condition.

### Exemplary Embodiment 2

The following describes a second exemplary embodiment of the method of FIG. 6, where a list of orders, given a speed reference, is provided as input.

Recall that at constant speed, scaling can be used to convert between frequency and order domains. This means that reference orders can also be expressed as reference frequencies and vice versa. This variation of the implementation of the invention takes a reference speed and converts that to a reference frequency. The list of orders to track defines a subset of harmonic frequencies. Because these orders may be less than or greater than resonance frequencies, it cannot be assumed that order phase (ϕ_{order}) is a multiple (orderᵢ) of the fundamental phase (ϕ_{fund}). Therefore this case may be treated as using a list of arbitrary, but exactly known frequencies.

One version of this embodiment may operate as follows:

Reference speed, in RPM, e.g., rotational speed, may be converted to a reference frequency, in Hertz, e.g., a first reference frequency.

Orders may be converted to reference frequencies.

Then the technique (method elements) of exemplary embodiment 1 may be performed as described above.

FIG. 8 illustrates an exemplary graphical program implementing a version of exemplary embodiment 2, implementing phase compensation at specific orders. As with the graphical program of FIG. 7B, for testing and reference, this embodiment was implemented in the G graphical programming language. Before calling the graphical program shown in FIG. 8, other graphical programs were used to acquire signals from data acquisition hardware, select each analysis block, compute the complex-valued frequency spectrum, and specify reference-frequency components. The graphical program of FIG. 8 is configured to perform method elements regarding the complex-valued frequency spectrum corresponding to those of the program of FIG. 7B, but particularly directed to this order based embodiment.

As may be seen, the program receives orders to track, speed (RPM), a complex spectrum, and advanced span (Hz), as input, and generates a phase compensated complex spectrum as output.

As with the graphical program of FIG. 7B, the graphical program of FIG. 8 includes indications or markers of general respective portions that perform corresponding parts of the technique described above, where the indications are integer labels 1-4 and the indicated portions generally correspond as follows:

Portion “1” operates to sort specified orders, e.g., from smallest to largest.

Portion “2” converts speed, input in units of RPM, to frequency in Hertz.

Portion “3” multiplies the sorted orders by reference frequency to generate a list of reference frequencies.

Portion “4” calls the graphical program of FIG. 7B to implement phase compensation at the reference frequencies, and after calling the exemplary graphical program of FIG. 7B, additional programs, e.g., graphical programs, may be used to vector average the phase-compensated spectrum and analyze the average spectrum to determine machine condition.

Thus, in some embodiments, the method may further include receiving orders to track, rotational speed of the machine, a complex spectrum, and advanced span, sorting the orders, converting the rotational speed to a first reference frequency, and generating the specified reference frequencies by multiplying the sorted orders by the first reference frequency.

### Exemplary Embodiment 3

The following describes a third exemplary embodiment of the method of FIG. 6, where an estimated fundamental reference frequency is provided as input.

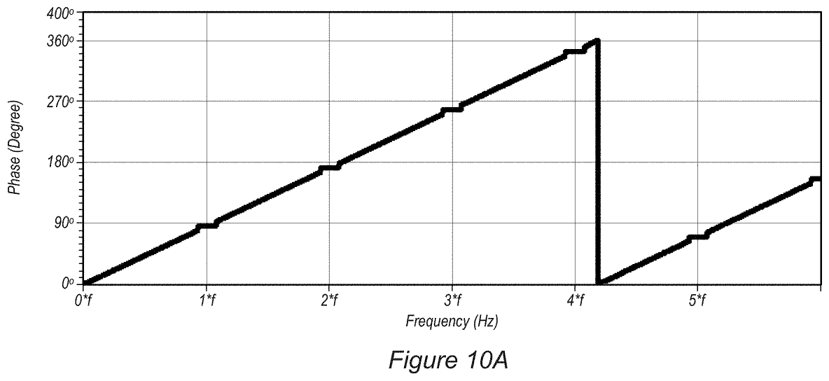

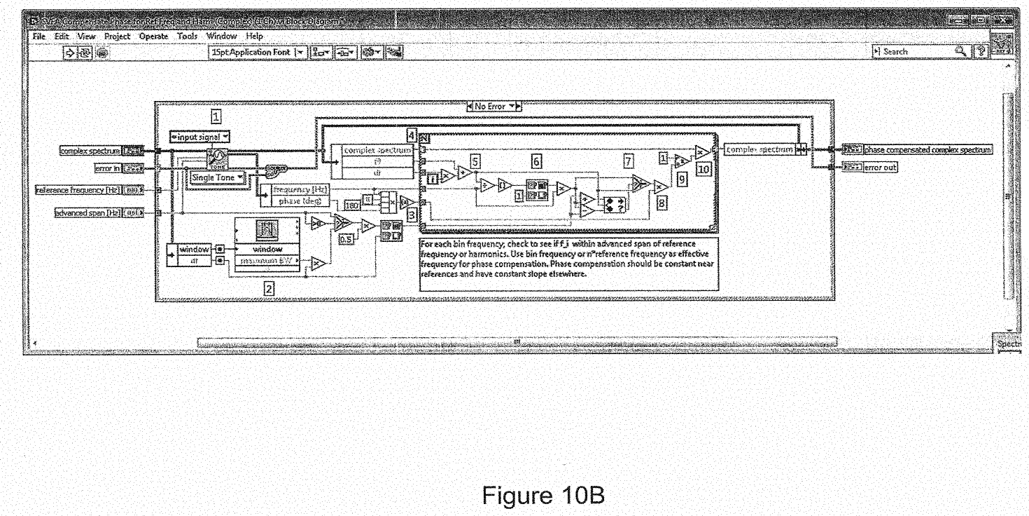

This embodiment relies on the integer multiple relationship between harmonics and their fundamental frequency, i.e., the method takes an estimated fundamental reference frequency and uses the relationship that the i^{th} harmonic phase is an integer multiple (hᵢ, where h denotes “harmonic”) of the fundamental phase, just as the i^{th} harmonic frequency is an integer multiple (hᵢ) of the fundamental frequency (f_{fund}). This assumption is often accurate and useful in other industries such as audio quality assurance and audio testing. Peak search may be used to identify the fundamental reference frequency component, including frequency, amplitude, and phase. The phase of the estimated fundamental reference frequency may be used as one measure of the relative delay between the acquired signal and the current analysis block. Modeling this time delay in the frequency domain determines the slope, in units of rad/Hz, of the phase compensation vector. If the bin frequency is within the advanced span of a harmonic frequency, the phase may be compensated by the i^{th} harmonic phase (ϕᵢ=ϕ_{fund}*hᵢ). If the bin is outside the advanced span, the compensation phase may be calculated as (ϕ_{bin}=ϕ_{fund}*f_{bin}/f_{fund}). An exemplary phase model for a fundamental reference frequency and integer harmonic components is shown in FIG. 10A.

One version of this (third exemplary) embodiment may operate as follows:

As noted above, an estimated fundamental reference frequency may be received, e.g., a first reference frequency.

An analog signal may be acquired via the data-acquisition system (or device), e.g., as per method element 602 above.

For each analysis block, e.g., selected as per method element 604 above:

The complex-valued frequency spectrum may be computed, e.g., via discrete Fourier transform (DFT), e.g., as per method element 606, above.

The (actual) fundamental reference frequency component may be identified at or near the estimated fundamental reference frequency, including identifying the frequency, amplitude, and phase of the fundamental reference frequency component.

The phase compensation vector element or portion which adjusts phase of the identified fundamental reference frequency component to a specified constant reference phase value, e.g., zero, may be constructed, where relative time delay may be modeled or interpreted as a linear scaling of phase versus frequency, and phase is held constant within the advanced span of the fundamental reference frequency or integer harmonic. Note that only the identified fundamental reference frequency is utilized here, i.e., reference frequency components corresponding to harmonics of the fundamental reference frequency are not explicitly identified, as their respective phase adjustments are computed based on an assumed linear relationship such as the exemplary phase model shown in FIG. 10A.

Further portions of the phase compensation vector corresponding to harmonics of the first reference frequency may be computed based on the constructed phase compensation vector portion and a phase based model of relative time delay between the first reference frequency component and respective analysis blocks.

The complex-valued phase compensation vector, or relevant element or portion thereof, may be multiplied with the complex-valued frequency spectrum of the analysis block, thereby phase compensating the complex-valued frequency spectrum of the analysis block. Any subset of the complex-valued frequency spectrum may be phase compensated.

Once all the analysis blocks have been processed (phase adjusted/compensated), the phase-compensated frequency spectra may be vector averaged, e.g., as per method element 614 above, thereby generating a phase adjusted frequency referenced vector averaged spectrum.

Reference frequency components may then be identified (i.e., measured or determined) in the phase adjusted frequency referenced vector averaged spectrum, as per method element 616 above, and in some embodiment, the identified components may be analyzed to determine machine condition, e.g., as per method element 618 above.

Thus, in the above embodiment, as with the above embodiments, for each bin frequency, the method checks to see if the bin frequency is within the advanced span of the frequency of interest or harmonics, and if the bin frequency is within the advanced span of a harmonic frequency, the phase is compensated by the harmonic phase, which in this embodiment is the phase of the fundamental frequency multiplied by the harmonic order, and if the bin is outside the advanced span, the compensation phase is calculated by multiplying the fundamental phase by the ratio of the bin frequency to the fundamental frequency.

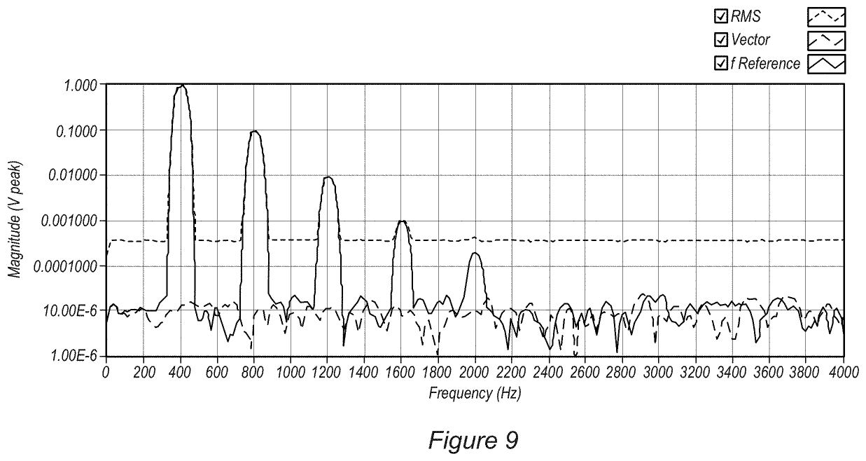

Note that for harmonically related components, the identification of higher harmonics may be improved by the high signal-to-noise ratio of the fundamental component. When sufficient phase-adjusted frequency-referenced vector averages are completed, accurate measurement of higher harmonic component amplitudes may be possible even when the amplitudes are below the averaged RMS noise floor as shown in FIG. 9, which presents an exemplary plot illustrating frequency referenced averaging for low amplitude harmonics, according to one embodiment.

In FIG. 9, the complex spectrum of a signal with sample rate of 51200 Hz and block size of 12800 samples has been computed. The graph is zoomed to the frequency range 0 to 1000 Hz to show the detail around the harmonic signal components. The improvement in the signal to noise ratio is achieved across the entire bandwidth 0 Hz to the Nyquist frequency. As the Figure legend indicates, the first (RMS) trace (dotted line) shows the RMS average spectrum, the second (Vector) trace (dashed line) shows a traditional vector average spectrum, and the third (f Reference) trace (solid line) shows a frequency referenced average spectrum, as per the present techniques. FIG. 9 also illustrates a worst case scenario for traditional vector averaging with no start trigger, in that the fundamental and harmonic components are undetectable in the vector average spectrum.

Table 1 below shows the frequencies, amplitudes, and measured spectral amplitudes for RMS and frequency referenced vector average spectra, per the third exemplary embodiment.

TABLE 1
Spectral Amplitudes of Harmonic Components

| | | RMS Average | Frequency-Referenced |
|---|---|---|---|
| Frequency | Amplitude | Spectrum | Average |
| (Hz) | (V) | (V) | Spectrum (V) |
| 100.1 | 1.0 | 1.000 | 1.000 |
| 200.2 | 0.1 | 0.1000 | 0.1000 |
| 300.3 | 0.01 | 0.01002 | 0.01002 |
| 400.4 | 0.001 | 0.001057 | 0.0009994 |
| 500.5 | 0.0002 | 0.0003928 | 0.0001958 |

FIG. 10B illustrates an exemplary graphical program (in the G programming language) implementing a version of the third exemplary embodiment, i.e., with respect to a fundamental reference frequency with harmonics. Before calling the graphical program shown in FIG. 10B, other programs, e.g., graphical programs, may be used to acquire an analog signal from data acquisition hardware, select each analysis block, compute the complex-valued frequency spectrum, and specify the fundamental reference frequency. Similar to the graphical programs of FIGS. 7 and 8, the graphical program of FIG. 10B may be configured to perform method elements regarding the complex-valued frequency spectrum corresponding to those of the program of FIG. 7B, but particularly directed to this exemplary embodiment.

As may be seen, the program receives a complex spectrum, a fundamental reference frequency (Hz), and an advanced span (Hz), as input, and generates a phase compensated complex spectrum as output.

As with the graphical programs of FIGS. 7B and 8, the graphical program of FIG. 10B includes indications or markers of general respective portions that perform corresponding parts of the technique described above, where the indications are integer labels 1-8 and the indicated portions generally correspond as follows:

Portion “1” operates to identify the fundamental reference frequency component, including frequency, amplitude, and phase.

Portion “2” calculates an advanced span if the user inputs a value less than or equal to a specified constant reference (phase) value, e.g., zero.

Portion “3” calculates the slope of the phase compensation vector with units of rad/Hz, using the fundamental reference frequency component phase.

Portion “4” iterates through the (DFT) bins in the complex-valued frequency spectrum, where, for each iteration:

Portion “5” determines the frequency of the current bin.

Portion “6” determines the closest harmonic frequency to the current bin frequency.

Portion “7” determines if the bin frequency is within the advanced span of the fundamental frequency or an integer harmonic, and if so, selects the closest harmonic (possibly including the fundamental frequency, which is considered to be the first harmonic) of the reference frequency, and if not, selects the current bin frequency.

Portion “8” multiplies the selected frequency with the slope of the phase compensation vector calculated in Portion “3”, thereby calculating the phase of the phase compensation vector at the current bin frequency.

Portion “9” constructs the phase compensation vector with magnitude 1 and the calculated phase from Portion “8”.

Portion “10” multiplies the complex-valued phase compensation vector with the complex-valued frequency spectrum subset (of the bin).

After calling the exemplary graphical program of FIG. 10B, additional programs, e.g., graphical programs, may be used to vector average the phase-compensated spectrum and analyze the average spectrum to determine machine condition.

In another embodiment that assumes a phase relationship based on frequency, the phase relationship may be based on a known or measured relative phase relationship between frequency components. Relative phase may be known for generated test signals such as, but not limited to, multitones, square waves, triangle waves, sawtooth waves, reverse sawtooth waves, steps, impulses, and other test signals with known phase relationships. In the case where there exists a known or assumed relative phase relationship between components, any frequency component may be used as a phase reference, and the known relative phase relationship may be superimposed on the phase model prior to performing phase compensation.

### Alternate Technique for Identification of Phase Differences Between Analysis Blocks

The below describes an alternate embodiment of frequency referenced vector averaging, using the time domain.

If this signal is stationary, then the analysis blocks may be viewed or considered as delayed versions of each other. For example, a 60 Hz sinusoid is acquired with 3 separate analysis blocks, with a sampling frequency of 1000 Hz. The first block begins at time t=0, and ends at t=1 s. The second block begins at time t=1.5 s and ends at t=2.5 s. The third begins at t=3.1 s and ends at 3.6 s. One can explicitly model the delay between the signal and the analysis blocks with a parameter, and use curve-fitting techniques to fit an extended model. The time delay between analysis blocks becomes a phase offset of the sinusoid in second and third analysis blocks. If the analysis blocks contain multiple reference frequency components, then the time delay may induce phase offsets for all frequency components in the additional analysis blocks. These phase offsets may be determined and used to phase adjust the respective components of the analysis blocks to make them coherent, which then facilitates the novel vector averaging technique disclosed herein, as described above.

An advantage of this approach is that all frequency components contribute to the identification of the delays between the analysis blocks, allowing for better resistance to noise. This implementation of the design uses all specified frequency components to estimate the delay between analysis blocks, whereas exemplary embodiment 3 uses just the fundamental. This procedure is applicable to complex frequency or order spectra calculated from time waveforms or resampled signals, as the first implementation of the invention described above.

### Exemplary Procedure

1. Acquire analog signals with the data-acquisition system.

2. Select m analysis blocks, each analysis block is a subset of acquired data to use for measurement analysis, e.g., corresponding to a respective time interval.

3. Specify expected fundamental and harmonic frequencies.

4. If necessary, provide initial guesses for curve fit.

5. Construct signal model based on a summation of n sinusoids:

$$b l o c {k}_{j} model = D C + {\sum }_{i = 0}^{n - 1} {A}_{i} * sin ( {ω}_{i} * t + {φ}_{i} + {δ}_{i} ) \qquad ( 1 )$$

where Aᵢ, ωᵢ, φᵢ are the amplitude, frequency, and phase of the i^{th} sinusoid present in all analysis blocks, and δᵢ is the phase difference or relative phase of the i^{th} sinusoid, due to a relative time delay, Δtⱼ, between the signal and the j^{th} analysis block. Note that the relationship between the relative phase and the time delay is δᵢ=Δtⱼ*2π*ωᵢ. By convention the first block is held as the reference, so δ₀=Δt₀=0. Note further that in some embodiments, the relative phase may be determined without explicit reference to or computation of the corresponding time delay, Δtⱼ.

6. Fit the signal model, using, for example, the Levenberg-Marquardt algorithm. Fitting returns the best-fit estimates for reference frequencies, amplitudes, and phases of each reference frequency (or FOI) component.

7. Analyze the identified components to determine machine condition.

Table 2 contains sample results from application of one embodiment of this alternative technique.

TABLE 2
Spectral Amplitudes of Harmonic Components Through Fitting

| Frequency | Amplitude | Recovered | Recovered |
|---|---|---|---|
| (Hz) | (V) | frequency (Hz) | Amplitude (V) |
| 100.1 | 1.0 | 100.1001 | 1.00003 |
| 200.2 | 0.1 | 200.2002 | 0.09995 |
| 300.3 | 0.01 | 300.3003 | 0.01001 |
| 400.4 | 0.001 | 400.4004 | 0.00100 |
| 500.5 | 0.0002 | 500.5005 | 0.00023 |

Following the above procedure:

1. The signal to be identified has fundamental frequency of 100.1 Hz, and several harmonics. Frequency and Amplitude columns in Table 2 detail the sinusoids to be identified. Gaussian noise is added to the signal with RMS=0.01 V. The sampling rate for all analysis blocks is 51.2 kHz, and the number of samples in each analysis block is 12800 samples.

2. Twenty analysis blocks were generated.

3. Fundamental frequency is estimated at 100 Hz, and we are interested in the fundamental and harmonic numbers 2, 3, 4, and 5.

4. Amplitude is estimated at 0.5 V for all sinusoids, and phase is estimated as 0 degrees. This is the initial guess passed to the fitting routine.
a. Note that this embodiment does not require that all blocks be sampled at the same rate, nor does it require that the number of samples in each analysis block be the same.

5. Given that we are interested in the fundamental and 2, 3, 4, and 5 harmonics, there are 15 sinusoidal parameters, and 19 delay parameters to estimate.

The model is fitted, e.g., using an implementation of Levenberg-Marquardt. The results are shown in Table 2, in the last two columns.

### Further Embodiments

The following presents further exemplary embodiments of the above techniques.

In one embodiment, machine speed or changes in machine speed may be detected based at least in part on the analog signals and measured frequencies of reference frequency components at constant orders of the machine speed. In some embodiments, the method may detect orders to track based at least in part on the analog signals and measured amplitudes of reference frequency components in the averaged phase compensated complex frequency spectra.

In some embodiments, the above vector averaging technique(s) may be applied to phase-adjusted frequency-referenced complex spectra of intermittent analysis blocks, i.e., may provide intermediate updates even when performing longer time averages by updating the average with each new analysis block. Vector averaging may thereby provide a progressively improving measurement using the phase compensated vector average spectrum, e.g., until a required signal-to-noise ratio is met. This technique may also be used to analyze machine data even from a machine that goes through multiple operating states. The present techniques only require continuous data within any one analysis block. However, the method may store multiple averages (in a memory medium), each associated with an operating state. As long as each analysis block matches the operating regime of one of the averages, the analysis block may be used to update that average. This relaxes the restriction of a completely time-invariant system.

Accordingly, in one embodiment, the method may further include storing the averaged spectrum of the first plurality of analysis blocks in persistent storage or memory.

A further analog signal from the sensor measuring the specified parameter indicative of machine condition of the operating machine may be acquired via the input, thereby generating a second digital signal. The second digital signal may include a second plurality of analysis blocks of data that are discontinuous with the first plurality of analysis blocks. The determining the phase compensated complex frequency spectrum (of method element 606 above) may be performed with respect to the second plurality of analysis blocks, thereby generating a phase compensated complex frequency spectrum for each analysis block of the second plurality of analysis blocks. The averaged spectrum of the first plurality of analysis blocks may be retrieved from persistent storage or memory, and the averaged spectrum of the first plurality of analysis blocks may be updated based on the phase compensated complex frequency spectra for each analysis block of the second plurality of analysis blocks. The updated averaged spectrum may be stored, e.g., in persistent storage or memory. Reference frequency components in the updated averaged spectrum may be identified, thereby generating average reference frequency components. The average reference frequency components in the updated averaged spectrum may then be analyzed to determine an updated machine condition. An indication of the updated machine condition may be output, e.g., to storage, another process, a log, a printer, a display device, etc.

As noted above, embodiments of the techniques disclosed herein may be implemented at least in part by textual and/or graphical programs. The below describes exemplary techniques for creating graphical programs.

### Creating a Graphical Program

A graphical program may be created on a computer system, e.g., the computer system 82 (or on a different computer system). The graphical program may be created or assembled by the user arranging on a display a plurality of nodes or icons and then interconnecting the nodes to create the graphical program. In response to the user assembling the graphical program, data structures may be created and stored which represent the graphical program. The nodes may be interconnected in one or more of a data flow, control flow, or execution flow format. The graphical program may thus comprise a plurality of interconnected nodes or icons which visually indicates the functionality of the program. As noted above, the graphical program may comprise a block diagram and may also include a user interface portion or front panel portion. Where the graphical program includes a user interface portion, the user may optionally assemble the user interface on the display. As one example, the user may use the Lab VIEW x graphical programming development environment to create the graphical program.

In an alternate embodiment, the graphical program may be created in 502 by the user creating or specifying a prototype, followed by automatic or programmatic creation of the graphical program from the prototype. This functionality is described in U.S. patent application Ser. No. 09/587,682 titled “System and Method for Automatically Generating a Graphical Program to Perform an Image Processing Algorithm”, which is hereby incorporated by reference in its entirety as though fully and completely set forth herein. The graphical program may be created in other manners, either by the user or programmatically, as desired. The graphical program may implement a measurement function that is desired to be performed by the instrument.

In some embodiments, a graphical program configured to receive and respond to user interface events may be created as follows. A graphical user interface or front panel for the graphical program may be created, e.g., in response to user input. The graphical user interface may be created in any of various ways, e.g., depending on the graphical programming development environment used. A block diagram for the graphical program may be created. The block diagram may be created in or using any graphical programming development environment, such as LabVIEW®, Simulink™, VEE, or another graphical programming development environment. The block diagram may be created in response to direct user input, e.g., the user may create the block diagram by placing or “dragging and dropping” icons or nodes on the display and interconnecting the nodes in a desired fashion. Alternatively, the block diagram may be programmatically created from a program specification. The plurality of nodes in the block diagram may be interconnected to visually indicate functionality of the graphical program. The block diagram may have one or more of data flow, control flow, and/or execution flow representations.

It is noted that the graphical user interface and the block diagram may be created separately or together, in various orders, or in an interleaved manner. In one embodiment, the user interface elements in the graphical user interface or front panel may be specified or created, and terminals corresponding to the user interface elements may appear in the block diagram in response. For example, when the user places user interface elements in the graphical user interface or front panel, corresponding terminals may appear in the block diagram as nodes that may be connected to other nodes in the block diagram, e.g., to provide input to and/or display output from other nodes in the block diagram. In another embodiment, the user interface elements may be created in response to the block diagram. For example, the user may create the block diagram, wherein the block diagram includes terminal icons or nodes that indicate respective user interface elements. The graphical user interface or front panel may then be automatically (or manually) created based on the terminal icons or nodes in the block diagram. As another example, the graphical user interface elements may be comprised in the diagram.

The graphical program may be executed on any kind of computer system(s) or reconfigurable hardware, as described above.

Although the embodiments above have been described in considerable detail, numerous variations and modifications will become apparent to those skilled in the art once the above disclosure is fully appreciated. It is intended that the following claims be interpreted to embrace all such variations and modifications.

We claim:

1. A non-transitory computer accessible memory medium that stores program instructions executable by a functional unit to:
cause a data acquisition device to acquire an analog signal from a sensor measuring a specified parameter indicative of a condition of a rotational machine, wherein the analog signal provides at least an indication of vibration of the rotational machine and includes frequency harmonic components indicative of corresponding components of the rotational machine;
generate a first digital signal based on the analog signal, wherein the first digital signal comprises a first plurality of analysis blocks of data, wherein each analysis block of data of the first plurality of analysis blocks of data is a time based subset of acquired data used for measurement analysis;
determine a phase compensated complex frequency spectrum for each analysis block of the first plurality of analysis blocks;
vector average the phase compensated complex frequency spectra of the first plurality of analysis blocks, thereby improving signal to noise ratio (SNR) at one or more specified reference frequencies and producing averaged spectra, wherein the one or more specified reference frequencies correspond to one or more characteristic machine and fault frequencies of the rotational machine;
identify reference frequency components in the averaged spectra, thereby generating average reference frequency components;
analyze the average reference frequency components to determine a machine condition of the rotational machine, wherein the machine condition corresponds to the indication provided by the analog signal; and
output an indication of the machine condition.

2. The non-transitory computer accessible memory medium of claim 1, wherein to determine a phase compensated complex frequency spectrum for each analysis block, the program instructions are executable to:
compute a complex valued frequency spectrum of the analysis block via a discrete Fourier transform (DFT);
specify at least one reference frequency;
construct a complex valued phase compensation vector that preserves magnitude while adjusting phase to achieve coherence between reference frequency components and the analysis block; and
phase compensate the complex valued frequency spectrum of the analysis block by multiplying the complex valued phase compensation vector with the complex-valued frequency spectrum.

3. The non-transitory computer accessible memory medium of claim 2,
wherein to determine a phase compensated complex frequency spectrum for each analysis block, the program instructions are executable to:
for each specified reference frequency:
determine at least one frequency bin within a frequency range centered at the reference frequency; and
wherein to phase compensate the complex valued frequency spectrum of the analysis block, the program instructions are executable to:
for each specified reference frequency:
multiply the complex valued phase compensation vector with components in the at least one frequency bin, thereby adjusting the at least one frequency bin to a specified constant phase reference value.

4. The non-transitory computer accessible memory medium of claim 3, wherein the frequency range is:
specified by user input; or
calculated according to one or more parameters of a time-domain window applied prior to the DFT.

5. The non-transitory computer accessible memory medium of claim 3,
wherein to phase compensate the complex valued frequency spectrum of the analysis block, the program instructions are executable to:
for each specified reference frequency:
identify a reference frequency component at or near the first reference frequency, including determining frequency, amplitude, and phase of the reference frequency component;
wherein to construct the complex valued phase compensation vector, the program instructions are executable to:
for each identified reference frequency component:
construct a phase compensation vector portion which adjusts phase of the identified reference frequency component to a specified constant phase reference value; and
wherein in phase compensating the complex valued frequency spectrum of the analysis block, frequency bins not in the advanced span of the specified reference frequency of the identified reference frequency component are not phase compensated.

6. The non-transitory computer accessible memory medium of claim 1, wherein the program instructions are further executable to:
receive a list of the one or more specified reference frequencies, wherein no phase relationship is assumed between the reference frequencies, and wherein a relative time delay for each specified reference frequency is modeled by phase of an associated reference frequency component.

7. The non-transitory computer accessible memory medium of claim 4, wherein the program instructions are further executable to:
receive orders to track, rotational speed of the machine, a complex spectrum, and advanced span;
sort the orders;
convert the rotational speed to a first reference frequency; and
generate the specified reference frequencies by multiplying the sorted orders by the first reference frequency.

8. The non-transitory computer accessible memory medium of claim 3, wherein the one or more reference frequencies are a first reference frequency, wherein the program instructions are further executable to:
receive the first reference frequency; and
identify a first reference frequency component at or near the first reference frequency, including determining frequency, amplitude, and phase of the first reference frequency component;
wherein to construct the complex valued phase compensation vector, the program instructions are executable to:
construct a phase compensation vector portion which adjusts phase of the first reference frequency component to a specified constant phase reference value; and
compute further portions of the phase compensation vector corresponding to harmonics of the first reference frequency based on the constructed phase compensation vector portion and a phase based model of relative time delay between the first reference frequency component and respective analysis blocks;
wherein in phase compensating the complex valued frequency spectrum of the analysis block:
frequency bins in the advanced span of a harmonic frequency of the first reference frequency are phase compensated by the i^{th} harmonic phase; and
frequency bins not in the advanced span are phase compensated based on the phase of the first reference frequency component, the frequency of the frequency bin, and the first reference frequency.

9. The non-transitory computer accessible memory medium of claim 8,
wherein the i^{th} harmonic phase is determined by a phase model:
ϕᵢ=ϕ_{fund}*hᵢ,
where ϕ_{fund} is the phase of the fundamental reference frequency component, and hᵢ denotes harmonic i of the fundamental reference frequency component; and
wherein frequency bins not in the advanced span of the first reference frequency are phase compensated according to:
ϕ_{bin}=ϕ_{fund}*f_{bin}/f_{fund},
where f_{bin} is the frequency of the frequency bin, f_{fund} is the first reference frequency, and ϕ_{bin} is the calculated phase of the phase compensation vector.

10. The non-transitory computer accessible memory medium of claim 2, wherein the signal is a stationary sum of sinusoids, and wherein the analysis blocks are considered to be time shifted versions of each other, wherein time delays with respect to a first analysis block of the first plurality of analysis blocks are modeled as relative phase differences of subsequent analysis blocks, and wherein the program instructions are further executable to:
specify a first reference frequency and a plurality of harmonics of the first reference frequency;
construct a signal model for each analysis block based on a summation of sinusoids present in all of the analysis blocks;
fit the signal models using the data of the analysis blocks, thereby generating best fit estimates for each reference frequency component, including best fit estimates of reference frequencies, amplitudes, and phases of each reference frequency component.

11. The non-transitory computer accessible memory medium of claim 10,
wherein the signal model for each block j comprises:
blockⱼmodel=DC+Σᵢ₌₀ⁿ⁻¹Aᵢ*sin(ωᵢ*t+φᵢ+δᵢ),
wherein DC denotes a direct current offset, Aᵢ, ωᵢ, δᵢ are the amplitude, frequency, and phase of the i^{th} sinusoid present in all analysis blocks, δᵢ is the phase of the i^{th} sinusoid due to the relative time delay, Δtⱼ, between the signal and the j^{th} analysis block, and wherein δᵢ=*Δtⱼ*2π*ωᵢ.

12. The non-transitory computer accessible memory medium of claim 1, wherein at least some of the analog signals are from sensors measuring homogeneous or heterogeneous parameters indicative of machine condition.

13. The non-transitory computer accessible memory medium of claim 1, wherein the program instructions are further executable to:
detect machine speed or changes in machine speed based at least in part on the analog signals and measured frequencies of reference frequency components at constant orders of the machine speed.

14. The non-transitory computer accessible memory medium of claim 1, wherein the program instructions are further executable to:
detect orders to track based at least in part on the analog signals and measured amplitudes of reference frequency components in the averaged phase compensated complex frequency spectra.

15. The non-transitory computer accessible memory medium of claim 1, wherein the program instructions are further executable to:
store the averaged spectrum of the first plurality of analysis blocks in persistent storage or memory;
acquire, via the input, a further analog signal from the sensor measuring the specified parameter indicative of machine condition of the rotational machine, thereby generating a second digital signal, wherein the second digital signal comprises a second plurality of analysis blocks of data that are discontinuous with the first plurality of analysis blocks;
perform said determining with respect to the second plurality of analysis blocks, thereby generating a phase compensated complex frequency spectrum for each analysis block of the second plurality of analysis blocks;
retrieve the averaged spectra of the first plurality of analysis blocks from persistent storage or memory;
update the averaged spectra of the first plurality of analysis blocks based on the phase compensated complex frequency spectrum for each analysis block of the second plurality of analysis blocks;
store the updated averaged spectra to persistent storage or memory;
identify reference frequency components in the updated averaged spectra, thereby generating average reference frequency components;
analyze the average reference frequency components in the updated averaged spectra to determine an updated machine condition; and
output an indication of the updated machine condition.

16. The non-transitory computer accessible memory medium of claim 1,
wherein to perform said vector averaging the phase compensated complex frequency spectra of the first plurality of analysis blocks, the program instructions are further executable to:
vector average the phase compensated complex frequency spectra of the first plurality of analysis blocks.

17. A computer-implemented method for determining machine condition, comprising:
acquiring an analog signal from a sensor measuring a specified parameter indicative of a condition of a rotational machine, wherein the analog signal provides at least an indication of vibration of the rotational machine and includes frequency harmonic components indicative of corresponding components of the rotational machine;
generating a first digital signal based on the analog signal, wherein the first digital signal comprises a first plurality of analysis blocks of data, wherein each analysis block of data of the first plurality of analysis blocks of data is a time based subset of acquired data used for measurement analysis;
determining a phase compensated complex frequency spectrum for each analysis block of the first plurality of analysis blocks;
vector averaging the phase compensated complex frequency spectra of the first plurality of analysis blocks, thereby improving signal to noise ratio (SNR) at one or more specified reference frequencies and producing averaged spectra, wherein the one or more specified reference frequencies correspond to one or more characteristic machine and fault frequencies of the rotational machine;
identifying reference frequency components in the averaged spectra, thereby generating average reference frequency components;
analyzing the average reference frequency components to determine a machine condition of the rotational machine, wherein the machine condition corresponds to the indication provided by the analog signal; and
outputting an indication of the machine condition.

18. The computer-implemented method of claim 17, further comprising:
storing the averaged spectra of the first plurality of analysis blocks in persistent storage or memory;
acquiring, via the input, a further analog signal from the sensor measuring the specified parameter indicative of machine condition of the rotational machine, thereby generating a second digital signal, wherein the second digital signal comprises a second plurality of analysis blocks of data that are discontinuous with the first plurality of analysis blocks;
performing said determining with respect to the second plurality of analysis blocks, thereby generating a phase compensated complex frequency spectrum for each analysis block of the second plurality of analysis blocks;
retrieving the averaged spectra of the first plurality of analysis blocks from persistent storage or memory;
updating the averaged spectra of the first plurality of analysis blocks based on the phase compensated complex frequency spectra for each analysis block of the second plurality of analysis blocks;
storing the updated averaged spectra to persistent storage or memory;
identifying reference frequency components in the updated averaged spectra, thereby generating average reference frequency components;
analyzing the average reference frequency components in the updated averaged spectra to determine an updated machine condition; and
outputting an indication of the updated machine condition.

19. The computer-implemented method of claim 17, further comprising:
detecting machine speed or changes in machine speed based at least in part on the analog signals and measured frequencies of reference frequency components at constant orders of the machine speed.

20. The computer-implemented method of claim 17, further comprising:
detect orders to track based at least in part on the analog signals and measured amplitudes of reference frequency components in the averaged phase compensated complex frequency spectra.

21. A system, comprising:
a functional unit;
an input, coupled to the functional unit; and
a memory, coupled to the functional unit, wherein the memory stores program instructions executable by the functional unit to:
acquire, via the input, an analog signal from a sensor measuring a specified parameter indicative of a condition of a rotational machine, wherein the analog signal provides at least an indication of vibration of the rotational machine and includes frequency harmonic components indicative of corresponding components of the rotational machine;
generate a first digital signal based on the analog signal, wherein the first digital signal comprises a first plurality of analysis blocks of data, wherein each analysis block of data of the first plurality of analysis blocks of data is a time based subset of acquired data used for measurement analysis;
determine a phase compensated complex frequency spectrum for each analysis block of the first plurality of analysis blocks;
vector average the phase compensated complex frequency spectra of the first plurality of analysis blocks, thereby improving signal to noise ratio (SNR) at one or more specified reference frequencies and producing averaged spectra, wherein the one or more specified reference frequencies correspond to one or more characteristic machine and fault frequencies of the rotational machine;
identify reference frequency components in the averaged spectra, thereby generating average reference frequency components;
analyze the average reference frequency components to determine a machine condition of the rotational machine, wherein the machine condition corresponds to the indication provided by the analog signal; and
output an indication of the machine condition.

22. The system of claim 21, wherein the program instructions are further executable to:
store the averaged spectra of the first plurality of analysis blocks in persistent storage or memory;
acquire, via the input, a further analog signal from the sensor measuring the specified parameter indicative of machine condition of the rotational machine, thereby generating a second digital signal, wherein the second digital signal comprises a second plurality of analysis blocks of data that are discontinuous with the first plurality of analysis blocks;
perform said determining with respect to the second plurality of analysis blocks, thereby generating a phase compensated complex frequency spectrum for each analysis block of the second plurality of analysis blocks;
retrieve the averaged spectra of the first plurality of analysis blocks from persistent storage or memory;
update the averaged spectra of the first plurality of analysis blocks based on the phase compensated complex frequency spectrum for each analysis block of the second plurality of analysis blocks;
store the updated averaged spectra to persistent storage or memory;
identify reference frequency components in the updated averaged spectra, thereby generating average reference frequency components;
analyze the average reference frequency components in the updated averaged spectra to determine an updated machine condition; and
output an indication of the updated machine condition

23. The system of claim 21, wherein the program instructions are further executable to:
detect machine speed or changes in machine speed based at least in part on the analog signals and measured frequencies of reference frequency components at constant orders of the machine speed.

24. The system of claim 21, wherein the program instructions are further executable to:
detect orders to track based at least in part on the analog signals and measured amplitudes of reference frequency components in the averaged phase compensated complex frequency spectra.
